(19) United States
(12) Patent Application Publication
(10) Pub. No.: US 2025/0176355 A1
(43) Pub. Date: May 29, 2025

(54) ORGANIC ELECTRONIC ELEMENT COMPRISING AN EMITTING AREA AND A TRANSMISSION AREA

(71) Applicant: DUK SAN NEOLUX CO., LTD., Cheonan-si (KR)

(72) Inventors: Won Joan CHEONG, Cheonan-si (KR); Wook SONG, Cheonan-si (KR); Hyun Ji OH, Cheonan-si (KR)

(73) Assignee: DUK SAN NEOLUX CO., LTD., Cheonan-si (KR)

(21) Appl. No.: 18/953,635

(22) Filed: Nov. 20, 2024

(30) Foreign Application Priority Data
Nov. 28, 2023 (KR) 10-2023-0167974

(51) Int. Cl. H10K 50/818; H10K 85/60

(52) U.S. Cl. CPC H10K 50/818; H10K 85/649

(57) ABSTRACT

Provided are an organic electronic element including a substrate and an anode disposed on the substrate, wherein a first part as an emitting area and a second part as a transmission area are on the anode; the first part and the second part include an organic material layer formed in common; the organic material layer includes a hole transport layer, an emitting layer, and an electron transport layer; a metal electrode is on the organic material layer of the first part, and a metal patterning layer is on the organic material layer of the second part; the metal patterning layer is formed to be thicker than the thickness of the metal electrode, and a fluorine compound is used as a metal patterning material, thereby forming a fine pattern of the electrode without using a shadow mask, and facilitating the production of a transparent display having high light transmittance, thereby facilitating the application of UDC.

### BACKGROUND

### Technical Field

The present invention relates to an organic electronic element comprising an emitting area and a transmission area, and more specifically, wherein the emitting area and the transmission area are coexist, and to an organic electronic element capable of patterning electrodes without using a shadow mask.

### Background Art

With the continuous advancement of display technology, users' demands for display devices are increasing. Terminal display devices are being developed in the direction of flexibility, full screen, and high integration, etc. For smartphone displays, bezel sizes are being reduced to increase the screen size, or bezel-less under displays are being developed. In this process, physical buttons on the front of the smartphone are disappearing into the screen, and technologies such as UDC (Under Display Camera) or UPS (Under Panel Sensor) are being developed. In particular, since UDC cameras can operate normally only when the display has high transmittance, precise patterning of the cathode is essential to increase transmittance.

Generally, there are two main methods used for electrode patterning. The first is to pattern the electrode in the desired area using a shadow mask, and the second is to create a pattern by irradiating the cathode with a laser.

However, the electrode patterning method using a shadow mask has a problem in that warping occurs during the high-temperature deposition process due to the typical material characteristics of the metal mask, which causes distortion of the mask shape and electrode pattern. Therefore, it is not commercially suitable for mass production of devices, as it inevitably requires time and cost to maintain the mask.

Additionally, the method of patterning electrodes using a laser causes the inconvenience of having to determine the type and intensity of the laser so that the substrate is not damaged in the way the electrodes are patterned due to the unique properties of the laser.

### PRIOR ART LITERATURE

### Patent Document

(patent document 1) Korean document 10-2023-0008590

### DETAILED DESCRIPTION OF THE INVENTION

### Summary

The present invention aims to provide an optimal organic electronic element capable of forming a fine pattern of an electrode without using a shadow mask by forming a metal patterning layer thicker than the thickness of a metal electrode, and having high light transmittance to implement a full-screen display such as a UDC.

### Technical Solution

In one aspect, the present invention provides an organic electronic element comprising: a substrate; an anode disposed on the substrate; wherein a first part as an emitting area and a second part as a transmission area are on the anode; wherein the first part and second part comprise an organic material layer formed in common, wherein the organic material layer comprises a hole transport layer, an emitting layer, and an electron transport layer, wherein the metal electrode exists on the organic material layer of the first part, and a metal patterning layer exists on the organic material layer of the second part, wherein the metal patterning layer is formed thicker than the thickness of the metal electrode.

In another aspect, the present invention provides an electronic device comprising the organic electronic element.

### Effects of the Invention

The present invention relates to an organic electronic element comprising a metal patterning layer formed on the outside of a metal electrode, wherein the metal patterning layer is formed to be thicker than the thickness of the metal electrode, and a fluorine compound is used as a metal patterning material, thereby forming a fine pattern of the electrode without using a shadow mask, and facilitating the production of a transparent display having high light transmittance, thereby facilitating the application of UDC.

### BRIEF DESCRIPTION OF THE DRAWINGS

FIG. 1 to FIG. 14 are exemplary diagrams of organic electroluminescent devices according to the present invention.

### DETAILED DESCRIPTION

When adding reference signs to components in each drawing, it should be noted that identical components are given the same signs as much as possible even if they are shown in different drawings. In addition, when describing the present invention, if it is determined that a detailed description of a related known configuration or function may obscure the gist of the present invention, the detailed description will be omitted.

When the words “comprises,” “has,” “consists of,” etc. are used in this specification, other parts may be added, unless “only” is used. When a component is expressed in the singular, it may comprise cases where it includes the plural unless there is a special explicit description.

Additionally, in describing components of the present invention, terms such as first, second, A, B, (a), (b), etc. may be used. These terms are only intended to distinguish one component from another and do not limit the nature, order, or sequence of the component. When a component is described as being “connected,” “coupled,” or “connected” to another component, it should be understood that the component may be directly connected or connected to that other component, but that there may also be another component “connected,” “coupled,” or “connected” between the components.

Additionally, when a component such as a layer, membrane, region, or plate is said to be “on” or “over” another component, it should be understood that this includes not only cases where it is “directly on” the other component, but also cases where there are other components in between. Conversely, when we say that a component is “directly above” another part, it should be understood that there is no intervening part.

As used in this specification and the appended claims, unless otherwise stated, the following terms have the following meanings:

As used herein, the term “halo” or “halogen” refers to fluorine (F), bromine (Br), chlorine (Cl) or iodine (I), unless otherwise specified.

As used herein, the term “alkyl” or “alkyl group” has a single bond of 1 to 60 carbon atoms, unless otherwise specified, and means saturated aliphatic functional radicals including a linear alkyl group, a branched chain alkyl group, a cycloalkyl group (alicyclic), an cycloalkyl group substituted with an alkyl or an alkyl group substituted with a cycloalkyl.

As used herein, the terms “alkenyl group” or “alkynyl group” have a double or triple bond of 2 to 60 carbon atoms, respectively, unless otherwise specified, and include a straight or branched chain group, but not limited thereto.

As used herein, the term “cycloalkyl” refers to an alkyl forming a ring having 3 to 60 carbon atoms unless otherwise specified, but is not limited thereto.

As used herein, the term “alkoxyl group”, “alkoxy group”, or “alkyloxy group” refers to an alkyl group to which an oxygen radical is attached, and has 1 to 60 carbon atoms, unless otherwise specified, but is not limited thereto.

As used herein, the term “aryloxyl group” or “aryloxy group” refers to an aryl group to which an oxygen radical is attached, and has 6 to 60 carbon atoms unless otherwise specified, but is not limited thereto.

As used herein, the term “alkylthio group” refers to an alkyl group to which a sulfur radical is attached, and has 1 to 60 carbon atoms unless otherwise specified, but is not limited thereto.

As used herein, the term “arylthio group” refers to an aryl group to which a sulfur radical is attached, and has 1 to 60 carbon atoms unless otherwise specified, but is not limited thereto.

As used herein, the terms “aryl group” and “arylene group” each have 6 to 60 carbon atoms, and are not limited thereto, unless otherwise specified. In the present invention, an aryl group or an arylene group means a single ring or multiple ring aromatic, and includes an aromatic ring formed by a neighboring substituent joining or participating in a reaction. For example, the aryl group may be a phenyl group, a biphenyl group, a fluorene group, or a spirofluorene group.

The prefix “aryl” or “ar” means a radical substituted with an aryl group. For example, an arylalkyl may be an alkyl substituted with an aryl, and an arylalkenyl may be an alkenyl substituted with aryl, and a radical substituted with an aryl has a number of carbon atoms as defined herein. Also, when prefixes are named subsequently, it means that substituents are listed in the order described first. For example, an arylalkoxy means an alkoxy substituted with an aryl, an alkoxylcarbonyl means a carbonyl substituted with an alkoxyl, and an arylcarbonylalkenyl also means an alkenyl substituted with an arylcarbonyl, wherein the arylcarbonyl may be a carbonyl substituted with an aryl.

As used herein, the term “heterocyclic group” includes one or more heteroatoms unless otherwise specified, has 2 to 60 carbon atoms, includes any one of a single ring or multiple ring, and may include heteroaliphadic ring and heteroaromatic ring. The heterocyclic group may also be formed in conjunction with an adjacent functional groups.

As used herein, the term “heteroatom” refers to N, O, S, P or Si unless otherwise specified.

Additionally, ‘heterocyclic group’ refers to a monocyclic type containing a hetero atom, a ring aggregate, a fused multiple ring system, a spiro compound, and the like. Also, a compound including a heteroatom group such as SO₂, P═O, etc., as in the following compound instead of carbon forming a ring, may also be included in the heterocyclic group.

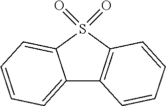 [SMILES: O=S1(=O)c2ccccc2-c2ccccc21]

The term “aliphatic ring group” used in the present invention refers to a cyclic hydrocarbon other than an aromatic hydrocarbon, and includes a single ring type, a ring aggregate, a fused multiple ring system, a spiro compound, etc., and unless otherwise specified, means the number of carbon atoms 3 to 60 rings, but is not limited thereto. For example, even when benzene, which is an aromatic ring, and cyclohexane, which is a non-aromatic ring, are fused, it corresponds to an aliphatic ring.

The term “fluorenyl group”, “fluorenylene group”, and “fluorentriyl group” used in the present invention means a monovalent, divalent or trivalent functional group in which R, R′ and R″ in each of the following structures are all hydrogen, unless otherwise specified, and “substituted fluorenyl group”, “substituted fluorenylene group” or “substituted fluorentriyl group” means that at least one of the substituents R, R′ and R″ is a substituent other than hydrogen, and includes cases in which R and R′ are bonded to each other to form a spiro compound together with the carbon to which they are attached. In the present specification, the fluorenyl group, fluorenylene group, and fluorentriyl group may all be referred to as fluorene groups regardless of the valence.

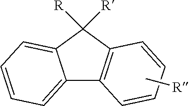

In the present specification, the ‘group name’ corresponding to the aryl group, arylene group, heterocyclic group, etc. exemplified as examples of each symbol and its substituents may be described as ‘the name of the group reflecting the valence’, but is described as the ‘name of the parent compound’. For example, in the case of ‘phenanthrene’, a type of aryl group, the monovalent ‘group’ can be written as ‘phenanthryl’ and the divalent group as ‘phenantrylene’, etc., by distinguishing the valence, but it can also be written as the parent compound name ‘phenanthrene’ regardless of the valence. Similarly, in the case of pyrimidine, it can be written as ‘pyrimidine’ regardless of the valence, or it can be written as the ‘group name’ of the valence, such as pyrimidinyl, for monovalent, or pyrimidinylene, for divalent. In addition, in the present specification, in describing the name of the compound or the name of a substituent, numbers or alphabets indicating positions may be omitted. For example, pyrido[4,3-d]pyrimidine to pyridopyrimidine, benzofuro[2,3-d]pyrimidine to benzofuropyrimidine, 9,9-dimethyl-9H-fluorene can be described as dimethylfluorene and the like. Therefore, both benzo[g]quinoxaline and benzo[f]quinoxaline can be described as benzoquinoxaline.

In addition, unless there is an explicit explanation, the formula used in the present invention is the same as the definition of the substituent by the exponent definition of the following formula.

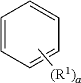

Here, when a is an integer of 0, the substituent R¹ is absent, when a is an integer of 1, the sole substituent R¹ is linked to any one of the carbon constituting the benzene ring, when a is an integer of 2 or 3, each is bonded as follows, where R¹ may be the same or different from each other, when a is an integer of 4 to 6, it is bonded to the carbon of the benzene ring in a similar manner, while the indication of the hydrogen bonded to the carbon forming the benzene ring is omitted.

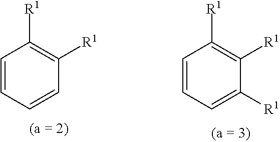

Also, unless otherwise stated herein, when representing a condensed ring, the number in ‘number-condensed ring’ indicates the number of rings to be condensed. For example, a form in which 3 rings are condensed with each other, such as anthracene, phenanthrene, benzoquinazoline, etc., may be expressed as a 3-condensed ring.

In addition, unless otherwise stated herein, when a ring is expressed in the form of a ‘numeric-atom’, such as a 5-membered ring, a 6-membered ring, etc., the number in ‘number-atom’ indicates the number of elements forming the ring. For example, thiophene or furan may correspond to a 5-membered ring, and benzene or pyridine may correspond to a 6-membered ring.

In addition, unless otherwise stated herein, a ring formed by bonding adjacent groups to each other may be selected from the group consisting of a C₆-C₆₀ aromatic ring group; fluorenyl group; C₂-C₆₀ heterocyclic group containing at least one heteroatom of O, N, S, Si or P; and C₃-C₆₀ aliphatic ring group;

At this time, unless otherwise stated herein, the term ‘adjacent groups’ refers to the following formula as an example, includes not only R¹ and R², R² and R³, R³ and R⁴, R⁵ and R⁶, but also R⁷ and R⁸ that share one carbon, and may include substituents bonded to non-adjacent ring constituent elements (such as carbon or nitrogen), such as R¹ and R⁷, R¹ and R⁸, or R⁴ and R⁵. That is, when there is a substituent on a ring constituent element such as carbon or nitrogen immediately adjacent to it, they may be adjacent groups, but if no substituent is bonded to a ring component at the immediately adjacent position, it may be a group adjacent to the substituent bonded to the next ring component, and also, substituents bonded to the same ring constituent carbons can be said to be adjacent groups.

When substituents bonded to the same carbon as R⁷ and R⁸ in the following formulas are bonded to each other to form a ring, a compound including a spiro moiety may be formed.

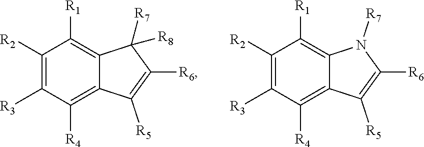

In addition, in the present specification, the expression ‘adjacent groups may be bonded to each other to form a ring’ is used in the same meaning as ‘adjacent groups are bonded to each other to selectively form a ring’, and means to a case in which at least one pair of adjacent groups are bonded to each other to form a ring.

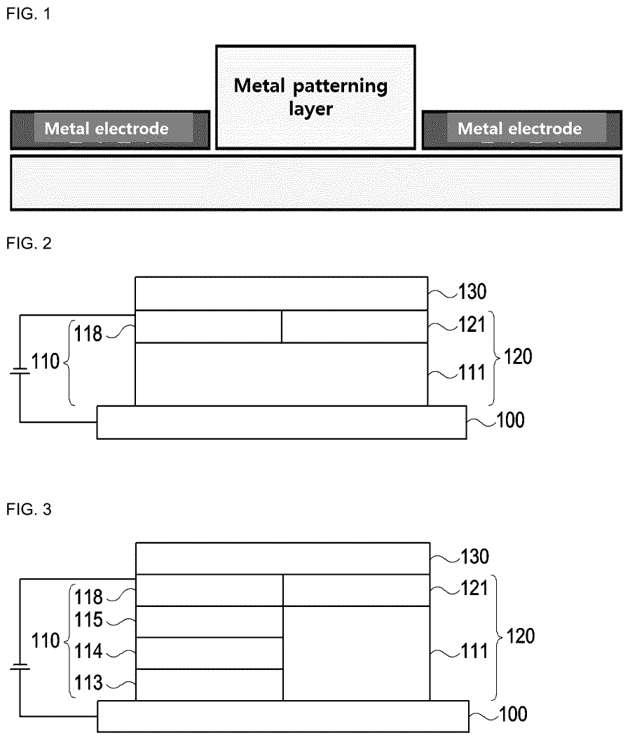

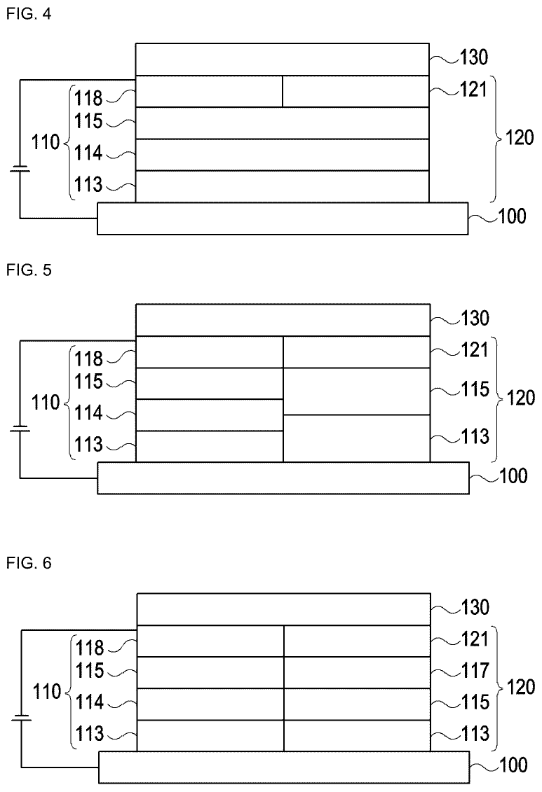

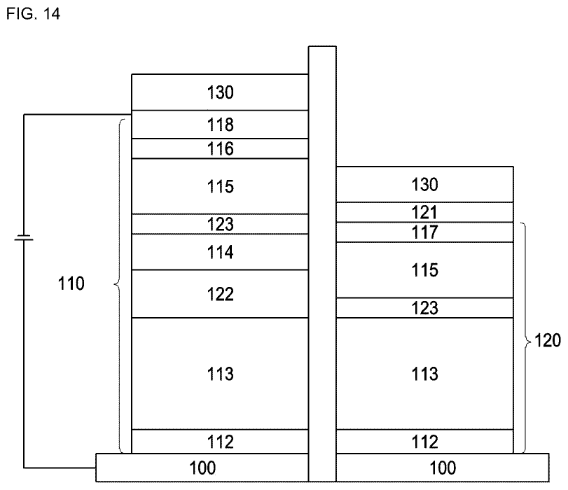

Hereinafter, an organic electronic element according to an embodiment of the present invention will be described in detail with reference to the attached FIGS. 1 to 14.

FIGS. 1 to 14 are drawings schematically illustrating the configuration of an organic electronic element according to one embodiment of the present invention.

FIG. 1 is a simplified drawing illustrating the laminated structure of an organic electronic element, an organic electronic element according to one embodiment of the present invention comprises a metal electrode and a metal patterning layer on a substrate; wherein the metal patterning layer is formed on an outer side of the metal electrode, and at this time, the metal patterning layer is formed thicker than the thickness of the metal electrode. In FIG. 1, the height, area, formation location, etc. of the metal electrode and the metal patterning layer are not limited by these drawings.

Although not shown in FIG. 1, an organic electronic element according to one embodiment of the present invention comprise an anode sequentially on a substrate, wherein a first part as an emitting area and a second part as a transmission area are on the anode, wherein the first part and second part comprise an organic material layer formed in common, wherein a metal electrode is on the organic material layer of the first part, and a metal patterning layer exists on the organic material layer of the second part.

When the metal patterning layer is coated, the cathode is suppressed from being laid on the metal patterning layer depending on the structure of the compound and the fluorine content included in the metal patterning layer, and ultimately the cathode is laid in a very small amount or not laid at all.

At this time, the light transmittance is used to determine the amount of electrode material present on a surface in relation to the coating of the electrode (electrically conductive material). This is because the electrode material contains metal, and electrically conductive materials such as metals attenuate and/or absorb light. Therefore, a surface can be considered to have virtually no electrically conductive material if its light transmittance exceeds 90% in the visible region of the electromagnetic spectrum.

Through this, the pixels of the organic electronic element comprising the metal patterning layer have high transmittance and do not emit light, so they act as blanks, and due to the high transmittance, they can transmit light to various light-angle sensors (optical sensors) located underneath the substrate (TFT substrate) without optical noise. Therefore, in an organic electronic element comprising a metal patterning layer, when forming an organic layer on a substrate (ITO), an emitting layer may or may not be present, and since there is no cathode on the metal patterning layer, electricity does not flow and light is not emitted.

When a metal patterning layer using an organic thin film made of a metal patterning material that selectively repels metal is applied, the film can be formed by a vacuum deposition method, facilitating patterning of the cathode. However, when the thickness of the metal patterning layer and the thickness of the metal electrode are the same or the thickness of the metal patterning layer is thinner than the thickness of the metal electrode, the metal deposition hindrance effect is small, which makes precise patterning of the cathode difficult, thereby reducing the transmittance of the organic electronic element.

As a result, when the thickness of the metal patterning layer is thicker than the thickness of the metal electrode, the metal deposition hindrance effect is maximized, which can improve the transmittance, and the production of a transparent display with high light transmittance can be facilitated, making the application of UDC easier. Referring to FIGS. 2 to 14, an organic electronic element according to one embodiment of the present invention comprises an anode (100) sequentially formed on a substrate (not shown), wherein a first part (110) as an emitting area and a second part (120) as a transmission area are on the anode (100), wherein a third part (130) as a common region is on the first part (110) and the second part (120). The third part (130) is shown as being formed on the first part (110) and the second part (120), but may be formed on one of both surfaces of the anode (100) that is not in contact with the organic material layer or on one of both surfaces of the cathode (118) that is not in contact with the organic material layer. Also, the first part (110) and the second part (120) comprise an organic layer (111) formed in common, wherein the organic material layer (111) comprises a hole transport layer (113) and an electron transport layer (115), wherein a cathode (118) is formed on the organic material layer (111) of the first part (110), and a metal patterning layer (121) is formed on the organic material layer (111) of the second part (120).

In FIGS. 2 to 12, the height of the first part (110) and the height of the second part (120) are depicted as being the same, but their heights may be the same or different. Also, FIGS. 2 to 12 are schematic drawings for explaining the laminated structure of the organic electronic element, and the height, area, formation position, etc. of the first part (110) and the second part (120) are not limited by these drawings. However, it is preferable that the metal patterning layer (121) of the second part be formed thicker than the cathode (118) of the first part.

The anode (100) may be a permeable electrode. Typically, the material forming the transparent electrode may be selected from transparent conducting oxides (TCOs), such as, but not limited to, indium tin oxide (ITO), zinc oxide (ZnO), tin oxide (SnO₂), or indium zinc oxide (IZO), and combinations thereof. Additionally, the anode (100) may be used as a multi-layer comprising 2 or more layers.

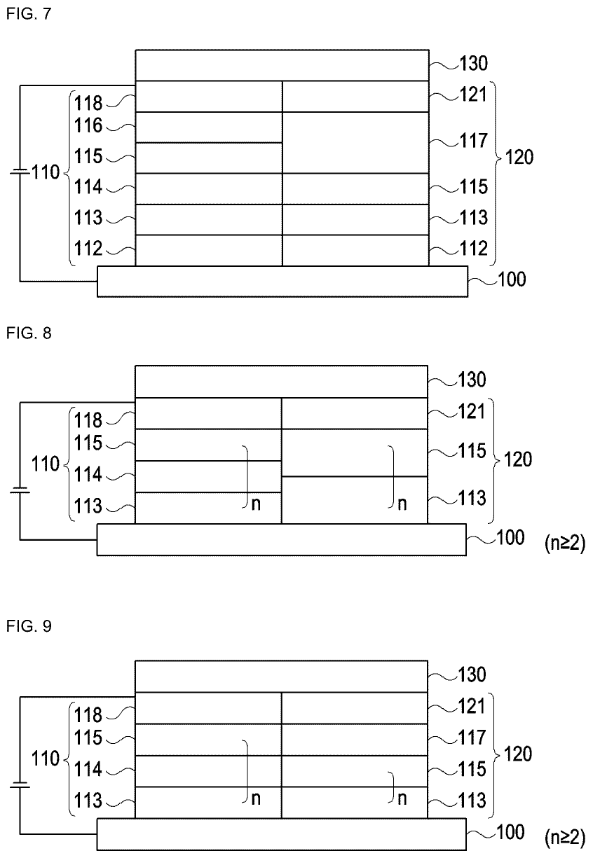

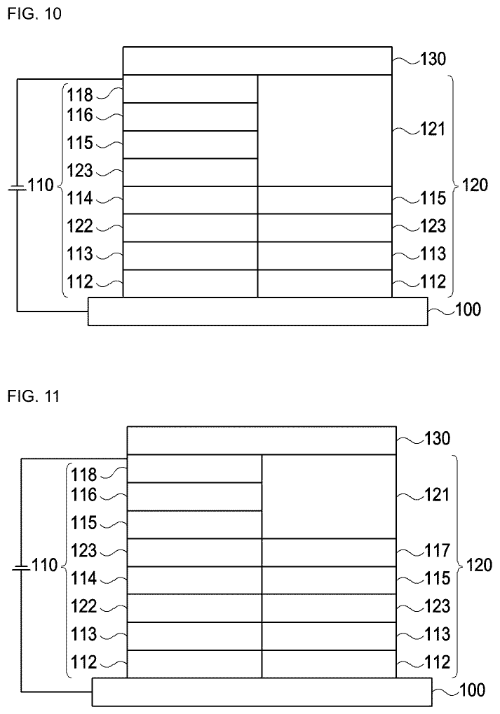

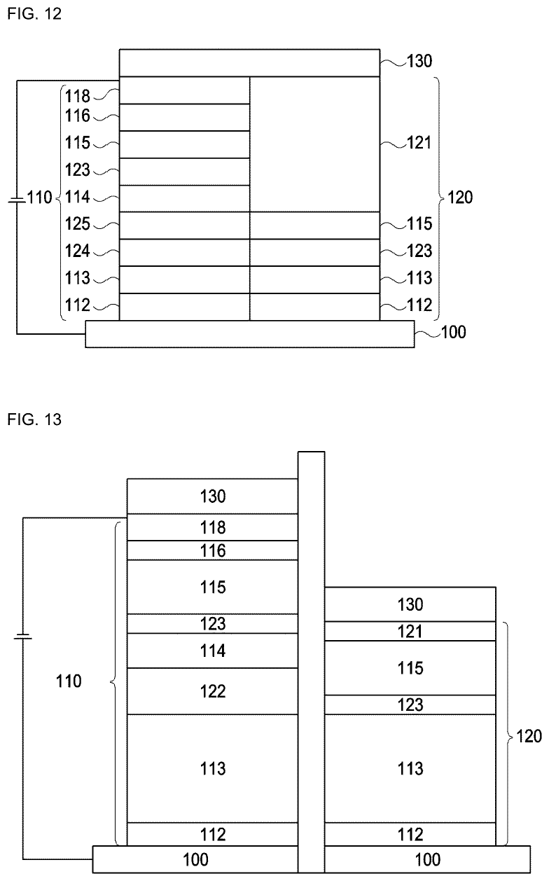

The first part (110) comprises a hole transport layer (113) and an electron transport layer (115). Preferably, as can be seen in FIGS. 3 to 14, the first part (110) further includes an emitting layer (114), wherein the emitting layer (114) is disposed between the hole transport layer (113) and the electron transport layer (115). That is, the first part (110) may comprise a hole transport layer (113), an emitting layer (114), an electron transport layer (115), and a cathode (118). Additionally, as can be seen in FIGS. 7, 10 to 14, a hole injection layer (112) may be further comprised between the anode (100) and the hole transport layer (113), wherein the hole transport layer (113) may be composed of one or more layers. That is, it can be composed of multiple hole transport layers (113) such as a first hole transport layer, a second hole transport layer, and a third hole transport layer, and the names of the multiple hole transport layers (113) can be different. For example, when the hole transport layer (113) is composed of 2 layers, the hole transport layer (113) adjacent to the emitting layer (114) may be named as an emitting auxiliary layer, a buffer layer, an electron-blocking layer, an exciton-blocking layer, etc. In FIG. 10, 12 to 14, it is named as an emitting auxiliary layer (122). Further, in FIG. 12, it can be seen that it is composed of a first emitting auxiliary layer (124) and a second emitting auxiliary layer (125). But, it is not limited to thereto. Also, an electron injection layer (116) may be further comprised between the electron transport layer (115) and the cathode (118), and the electron transport layer (115) may be composed of one or more layers. That is, it can be composed of multiple electron transport layers (115) such as a first electron transport layer, a second electron transport layer, and a third electron transport layer, and the names of the multiple electron transport layers (115) can be different. For example, when the electron transport layer (115) is composed of 2 layers, the electron transport layer (115) adjacent to the emitting layer (114) may be named as an auxiliary layer, a buffer layer, an A-ETL, a hole-blocking layer, etc. In FIGS. 10 to 14, it is named as a hole-blocking layer (123). For example, the first part (110) may be sequentially laminated in the order of a hole injection layer (112)/hole transport layer (113)/emitting auxiliary layer (122)/emitting layer (114)/hole blocking layer (123)/electron transport layer (115)/electron injection layer (116)/cathode (118) on the anode (100), but is not limited thereto.

As shown in FIGS. 8 and 9, the first part (110) may be formed in a form in which 2 or more stacks (ST) comprising a hole transport layer (113), an emitting layer (114), and an electron transport layer (115) are formed. Two or more sets (n>2) of stacks of multilayer organic material layers (111) may be formed between the anode (100) and the cathode (118), and a charge generation layer (CGL; not shown) may be formed between the stacks of organic material layers (111). That is, when n is 2, a hole transport layer (113) may be laminated again on the electron transport layer (115), and a charge generation layer may be comprised between the electron transport layer (115) and the hole transport layer (113). For example, it may sequentially comprise an anode (100), a first stack (first hole transport layer-first emitting layer-first electron transport layer), a charge generation layer, a second stack (second hole transport layer-second emitting layer-second electron transport layer), and a cathode (118). The charge generation layer can be placed between stacks, and serves to increase current efficiency and smoothly distribute charges.

The emission colors between stacks may be different, and the materials in each stack may be different. Additionally, electrons and holes are supplied from the CGL, the anode (100) and the cathode (118) to enable each of the emitting layers (114) to emit light. That is, each emitting layer (114) can emit light with a different color. When a plurality of emitting layers (114) are formed by a multilayer stack structure, it is possible to manufacture an organic emitting display device that emits white light by the mixing effect of light emitted from each emitting layer (114), and it is also possible to manufacture an organic emitting display device that emits light of various colors.

The charge generation layer may be formed of an n-doped layer and/or a p-doped layer for injecting electrons and holes, and may be selected from, for example, n and p conductive dopants, but is not limited thereto.

The hole injection layer (112) or hole transport layer (113) may be composed of any material commonly used as a hole injection/transport material, such as an aromatic or heteroaromatic amine compound and a carbazole derivative, but is not limited thereto.

Also, the hole injection layer (112) may be composed of one or more compounds, and the compound of the hole injection layer (112) and the compound of the hole transport layer (113) may be the same or different.

The emitting layer (114) may include a host and a dopant.

The host may be selected from any material commonly used as a host, such as, but not limited to, an aromatic or heteroaromatic amine compound, an azine compound, a condensed polycyclic aromatic compound, a carbazole compound, and the like. Additionally, the host may be composed of one or more compounds.

The dopant may be selected from any material commonly used as a dopant, such as a fluorescent luminescent compound, a phosphorescent luminescent compound, and a delayed fluorescent luminescent compound, and may be selected from, for example, a condensed polycyclic aromatic compound, a condensed polycyclic aromatic amine compound, a compound containing boron (B), a carbazole compound, an organometallic complex (an organometallic compound comprising iridium (Ir), osmium (Os), ruthenium (Rh), platinum (Pt), etc.), but is not limited thereto. Additionally, the dopant may consist of one or more compounds.

The electron injection layer (116) or electron transport layer (115) may be formed of a material selected from any material commonly used as an electron injection/transport material, such as a heteroaromatic compound such as an azine derivative, a carbazole derivative, a phenanthroline derivative, an imidazole derivative, a benzimidazole derivative, and a benzoxazole derivative, or a metal complex such as an aluminum (Al) complex and a zinc (Zn) complex, but is not limited thereto.

Additionally, the electron injection layer (116) may be composed of one or more compounds, and the compound of the electron injection layer (116) and the compound of the electron transport layer (115) may be the same or different. Additionally, the electron injection layer (116) may comprise a metal or a compound comprising a metal. In particular, it can be formed of a material selected from among materials having high electrical conductivity, such as silver (Ag), magnesium (Mg), aluminum (Al), ytterbium (Yb), copper (Cu), zinc (Zn), cadmium (Cd), gold (Au), nickel (Ni), cobalt (Co), iron (Fe), molybdenum (Mo), niobium (Nb), palladium (Pd), platinum (Pt), lithium (Li), sodium (Na), calcium (Ca), and combinations thereof, but is not limited thereto.

The cathode (118) is preferably composed of one or more metal materials, wherein the metal materials may be selected from magnesium (Mg), silver (Ag), aluminum (Al), lithium (Li), calcium (Ca), indium (In), and combinations thereof, and is preferably composed of a mixture of Mg and Ag, but is not limited thereto.

Additionally, the cathode (118) may be used as a multi-layer including 2 or more layers.

As shown in FIG. 6, the second part (120) may further comprise a patterning auxiliary photosensitive layer (117). Preferably, the patterning auxiliary photosensitive layer (117) may be placed under the metal patterning layer (121). Since the material currently applied to the metal patterning layer (121) has no or very weak photoluminescence properties, it may be difficult to measure its thickness using the photoluminescence properties. If the thickness of the metal patterning layer (121) is too thick, a coagulation phenomenon occurs, making it difficult to form a thin film with a uniform surface, making it difficult to secure uniform light transmittance and causing problems when additionally forming a thin film such as the third part (130).

Therefore, in order to easily measure the thickness of the metal patterning layer (121) by using optical characteristics, a patterning auxiliary photosensitive layer (117) with excellent photoluminescence characteristics can be formed under the metal patterning layer (121). The patterning auxiliary photosensitive layer (117) can be formed of a photosensitive organic material having a stronger photoluminescence intensity than the metal patterning layer (121) and optical properties that can be measured by an optical method. That is, after applying the patterning auxiliary photosensitive layer (117), the thickness of the metal patterning layer (121) can be measured using an ellipsometer.

The patterning auxiliary photosensitive layer (117) may comprise a compound comprising at least one heterocycle. The heterocycle may be preferably a C₂-C₆₀ heterocycle containing at least one heteroatom of O, N, S, Si and P, more preferably a C₂-C₃₀ heterocycle, and even more preferably a C₂-C₂₄ heterocycle, specifically, it may be, but is not limited to, oxazole, thiazole, benzoxazole, benzothiazole, pyridine, pyrimidine, pyrazine, triazine, quinoline, quinazoline, quinoxaline, imidazole, triazole, benzimidazole, benzotriazole, furan, thiophene, benzofuran, benzothiophene, indole, dibenzofuran, dibenzothiophene, carbazole, benzofuropyridine, benzothiophenopyridine, carboline, benzofuropyrimidine, benzothiophenopyrimidine, benzofuropyrazine, and benzothiophenopyrazine, etc.

By forming the third part (130), in the case of a top emission organic light emitting device, the optical energy loss due to SPPs (Surface Plasmon Polaritons) at the cathode (118) can be reduced, and in the case of a bottom emission organic light emitting device, the third part (130) can perform a buffering role for the first part (110) and the second part (120). In particular, when the light transmittance of the material of the third part (130) is high, the optical energy loss due to SPPs can be reduced when light emitted from the first part (110) passes through the third part (130) and is emitted.

The third part (130) may have a single-layer or multi-layer structure. Additionally, the third part (130) may be a single compound or a mixture of 2 or more compounds.

These organic material layers (111) may be manufactured using various deposition methods. For example, the organic material layer (111) can be manufactured using a deposition method such as PVD or CVD, and can be manufactured with a smaller number of layers by a solution process or solvent process other than a deposition method, such as a spin coating process, a nozzle printing process, an inkjet printing process, a slot coating process, a deep coating process, a roll-to-roll process, a doctor blading process, a screen printing process, or a thermal transfer method.

Preferably, the organic material layer (111) can be formed by vacuum deposition. However, since the organic material layer (111) according to the present invention can be formed by various methods, the scope of the present invention is not limited by the formation method.

The organic electronic element according to one embodiment of the present invention may be a front-emitting, back-emitting, or both-sided emitting type depending on the material used.

Additionally, the organic electronic element according to an embodiment of the present invention may be selected from the group consisting of an organic electroluminescent device, an organic solar cell, an organic photoreceptor, an organic transistor, a monochromatic lighting device, and a quantum dot display device.

Another embodiment of the present invention may comprise an electronic device comprising a display device comprising the organic electronic element of the present invention; and a control unit for driving the display device. Wherein, the electronic device may be a current or future wired/wireless communication terminal, and covers all kinds of electronic devices comprising mobile communication terminals such as mobile phones, navigation, game consoles, various TVs, various computers, etc. Preferably, the display device includes a transparent display, and the electronic device may comprise an Under Display Camera (UDC) or an Under Panel Sensor (UPS).

Hereinafter, an organic electronic element according to one aspect of the present invention will be described.

The present invention provides an organic electronic element comprising: a substrate; an anode disposed on the substrate; a first part as an emitting area; and a second part as a transmission area on the anode; wherein the first part and the second part comprise an organic layer formed in common, wherein the organic material layer comprises a hole transport layer, an emitting layer, and an electron transport layer, wherein a metal electrode is on the organic material layer of the first part, a metal patterning layer is on the organic material layer of the second part, wherein the metal patterning layer is formed to be thicker than the thickness of the metal electrode.

Additionally, the thickness of the metal patterning layer is formed to be at least twice that of the metal electrode.

Also, the thickness of the metal patterning layer is 100 Å to 300 Å.

Also, the metal patterning layer material comprises at least one fluorine (F) in the molecule.

Also, the metal patterning layer material comprises a compound represented by the Formula A.

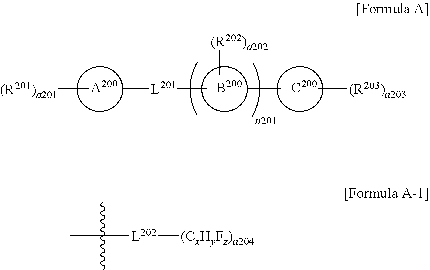

Wherein:
A²⁰⁰ ring, B²⁰⁰ ring and C²⁰⁰ ring are independently a C₆-C₆₀ aryl group; or a C₂-C₆₀ heteroaryl group including at least one heteroatom of O, N, S, Si or P;

When A²⁰⁰ ring, B²⁰⁰ ring and C²⁰⁰ ring are an aryl group, preferably an C₆-C₃₀ aryl group, more preferably an C₆-C₂₅ aryl group, for example, it may be phenyl, biphenyl, terphenyl, naphthalene and the like.

When A²⁰⁰ ring, B²⁰⁰ ring and C²⁰⁰ ring are a heteroaryl group, preferably a C₂-C₃₀ heteroaryl group, more preferably a C₂-C₂₄ heteroaryl group.
L²⁰¹ is selected from a group consisting of a single bond; NR²⁰⁴; CR²⁰⁴R²⁰⁵; SiR²⁰⁴R²⁰⁵; fluorinated a C₁-C₆₀ alkylene group; and fluorinated a C₂-C₂₀ alkenylene group;
When L²⁰¹ is fluorinate alkylene group, preferably fluorinated a C₂-C₃₀ alkylene group, more preferably fluorinated a C₂-C₂₄ alkylene group.

When L²⁰¹ is fluorinated a C₂-C₂₀ alkenylene group, preferably fluorinated a C₂-C₃₀ alkenylene group, more preferably fluorinated a C₂-C₂₄ alkenylene group.
L²⁰² is each independently selected from the group consisting of a single bond; a C₁-C₆₀ alkylene group; a C₂-C₂₀ alkenylene group; a C₂-C₂₀ alknylene group; a C₁-C₃₀ alkoxylene group; a C₆-C₆₀ aryloxylene group; a C₆-C₆₀ arylene group; a fluorenylene group; a C₂-C₆₀ heterocyclic group including at least one heteroatom of O, N, S, Si or P; a fused ring group of a C₃-C₆₀ aliphatic ring and a C₆-C₆₀ aromatic ring;
When L²⁰² is an alkylene group, preferably a C₁-C₃₀ alkylene group, and more preferably a C₁-C₂₄ alkylene group.

When L²⁰² is an alkoxylene group, preferably a C₁-C₂₄ alkoxylene group.

When L²⁰² is aryloxylene group, preferably a C₆-C₂₄ aryloxylene group.

When L²⁰² is an arylene group, preferably a C₆-C₆₀ arylene group, more preferably a C₆-C₂₀ arylene group, such as phenylene, biphenylene, naphthylene, terphenylene, anthracenylene, etc.

When L²⁰² is a heterocyclic group, preferably a C₂-C₃₀ heterocyclic group, more preferably a C₂-C₂₄ heterocyclic group, for example, it may be pyrazine, thiophene, pyridine, pyrimidoindole, 5-phenyl-5H-pyrimido[5,4-b]indole, quinazoline, benzoquinazoline, carbazole, dibenzoquinazoline, dibenzofuran, dibenzothiophene, benzothienopyrimidine, benzofuropyrimidine, phenothiazine, phenylphenothiazine, naphthobenzofuran, naphthobenzothiophene etc.

When L²⁰² is a fused ring group, preferably a fused ring group of a C₃-C₃₀ aliphatic ring and an C₆-C₆₀ aromatic ring, more preferably a fused ring group of an C₃-C₂₄ aliphatic ring and an C₆-C₂₄ aromatic ring.

R²⁰¹, R²⁰² and R²⁰³ are each independently the same or different, and each independently selected from the group consisting of hydrogen; deuterium; halogen; a C₆-C₆₀ aryl group; a fluorenyl group; a C₂-C₆₀ heterocyclic group including at least one hetero atom of O, N, S, Si or P; a fused ring group of a C₃-C₆₀ aliphatic ring and an C₆-C₆₀ aromatic ring; a C₁-C₆₀ alkyl group; a C₂-C₂₀ alkenyl group; a C₂-C₂₀ alkynyl group; a C₁-C₃₀ alkoxyl group; a C₆-C₆₀ aryloxy group; and a substituent represented by Formula A-1;
Provided that, at least one of R²⁰¹, R²⁰² and R²⁰³ is fluorine or a substituent represented by Formula A-1,
R²⁰⁴ and R²⁰⁵ are each independently selected from the group consisting of hydrogen; deuterium; halogen; a C₆-C₆₀ aryl group; a fluorenyl group; a C₂-C₆₀ heterocyclic group including at least one hetero atom of O, N, S, Si or P; a fused ring group of a C₃-C₆₀ aliphatic ring and an C₆-C₆₀ aromatic ring; a C₁-C₆₀ alkyl group; a C₂-C₂₀ alkenyl group; a C₂-C₂₀ alkynyl group; a C₁-C₃₀ alkoxyl group; and a C₆-C₃₀ aryloxy group; or R²⁰⁴ and R²⁰⁵ can be bonded to each other to form a ring,
When R²⁰¹, R²⁰², R²⁰³, R²⁰⁴ and R²⁰⁵ are an aryl group, preferably an C₆-C₃₀ aryl group, more preferably an C₆-C₂₅ aryl group, for example, it may be phenyl, biphenyl, terphenyl, naphthalene, phenanthrene and the like.

When R²⁰¹, R²⁰², R²⁰³, R²⁰⁴ and R²⁰⁵ are a heterocyclic group, preferably a C₂-C₃₀ heterocyclic group, more preferably a C₂-C₂₄ heterocyclic group, for example, it may be pyrazine, thiophene, pyridine, pyrimidoindole, 5-phenyl-5H-pyrimido[5,4-b]indole, quinazoline, benzoquinazoline, carbazole, dibenzoquinazoline, dibenzofuran, dibenzothiophene, benzothienopyrimidine, benzofuropyrimidine, phenothiazine, phenylphenothiazine, naphthobenzofuran, naphthobenzothiophene etc.

When R²⁰¹, R²⁰², R²⁰³, R²⁰⁴ and R²⁰⁵ are a fused ring group, preferably a fused ring group of a C₃-C₃₀ aliphatic ring and an C₆-C₆₀ aromatic ring, more preferably a fused ring group of an C₃-C₂₄ aliphatic ring and an C₆-C₂₄ aromatic ring.

When R²⁰¹, R²⁰², R²⁰³, R²⁰⁴ and R²⁰⁵ are an alkyl group, preferably a C₁-C₃₀ alkyl group, more preferably a C₁-C₂₄ alkyl group,
When R²⁰¹, R²⁰², R²⁰³, R²⁰⁴ and R²⁰⁵ are an alkoxyl group, preferably a C₁-C₂₄ alkoxyl group,
When R²⁰¹, R²⁰², R²⁰³, R²⁰⁴ and R²⁰⁵ are an aryloxy group, preferably a C₆-C₂₄ aryloxy group,
n201 is an integer from 0 to 3, and a201, a202, a203 and a204 are independently integers from 1 to 10,
x is an integer from 1 to 50, y+z is 2x+1 or 2x,
but z is an integer greater than or equal to 1,

The x is preferably an integer from 1 to 20, more preferably an integer from 5 to 15, and even more preferably an integer from 5 to 12,
wherein the aryl group, heteroaryl group, arylene group, heterocyclic group, fluorenyl group, fluorenylene group, fused ring group, alkyl group, alkenyl group, alkynyl group, alkoxyl group, aryloxy group, alkylene group, alkenylene group, alkynylene group, alkoxylene group and aryloxylene group may be substituted with one or more substituents selected from the group consisting of deuterium; halogen; silane group; siloxane group; boron group; germanium group; cyano group; nitro group; C₁-C₂₀ alkylthio group; C₁-C₂₀ alkoxyl group; C₆-C₂₀ aryloxy group; C₁-C₂₀ alkyl group; C₂-C₂₀ alkenyl group; C₂-C₂₀ alkynyl group; C₆-C₂₀ aryl group; C₆-C₂₀ aryl group substituted with deuterium; C₆-C₂₀ aryl group substituted with halogen; a fluorenyl group; C₂-C₂₀ heterocyclic group; C₃-C₂₀ cycloalkyl group; C₇-C₂₀ arylalkyl group; and C₈-C₂₀ arylalkenyl group; additionally, the hydrogens of these substituents may be further substituted with one or more deuteriums, also the substituents may be bonded to each other to form a saturated or unsaturated ring, wherein the term ‘ring’ means a C₃-C₆₀ aliphatic ring or a C₆-C₆₀ aromatic ring or a C₂-C₆₀ heterocyclic group or a fused ring formed by the combination thereof.

Formula A can be represented by any one of Formulas B to D.

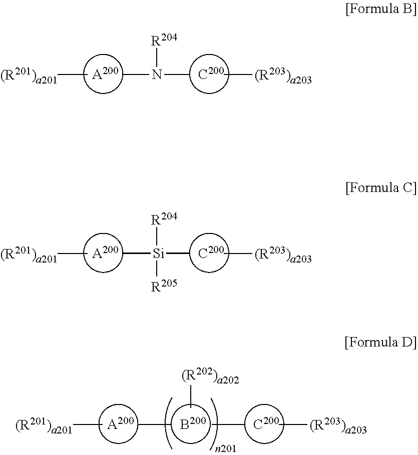

Wherein: A²⁰⁰ ring, B²⁰⁰ ring, C₂₀₀ ring, R²⁰¹, R²⁰², R²⁰³, R²⁰⁴, R²⁰⁵, a201, a202, a203 and n201 are the same as defined in Formula A.

Formula A can be represented by Formula E.

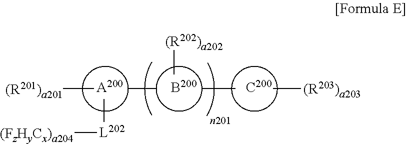

Wherein: A²⁰⁰ ring, B²⁰⁰ ring, C₂₀₀ ring, R²⁰¹, R²⁰², R²⁰³, a201, a202, a203 and n201 are the same as defined in Formula A.

a204, L²⁰², x, y and z are the same as defined in Formula A-1.

Formula A can be represented by Formula F

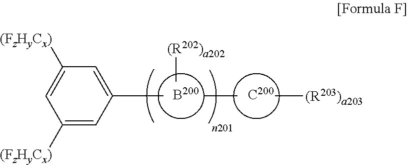

Wherein: B²⁰⁰ ring, C²⁰⁰ ring, R²⁰², R²⁰³, a202, a203 and n201 are the same as defined in Formula A.

x, y and z are as defined in Formula A-1.

Formula A may be any one of the following compounds P3-1 to P3-114, but is not limited thereto:

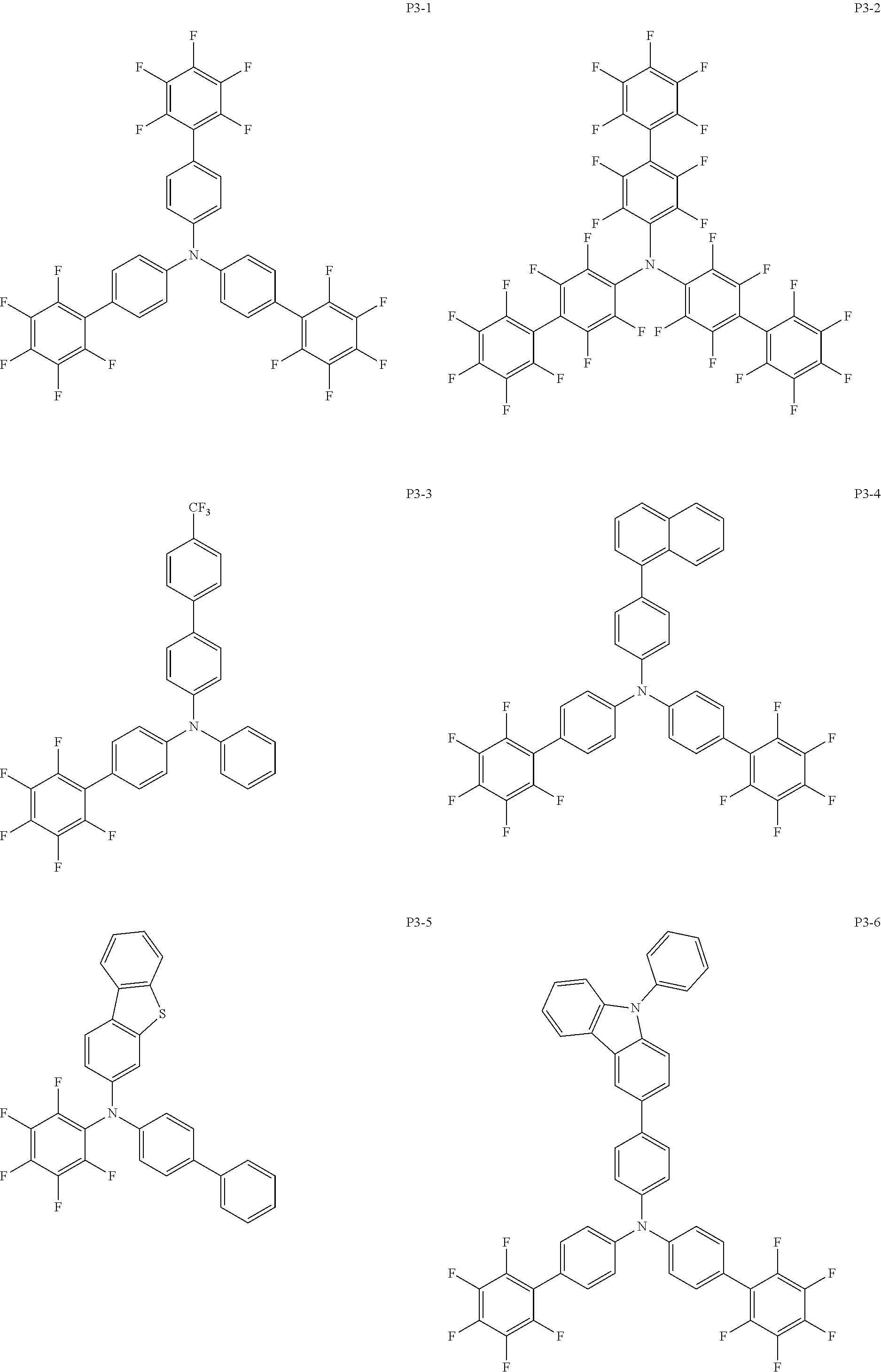

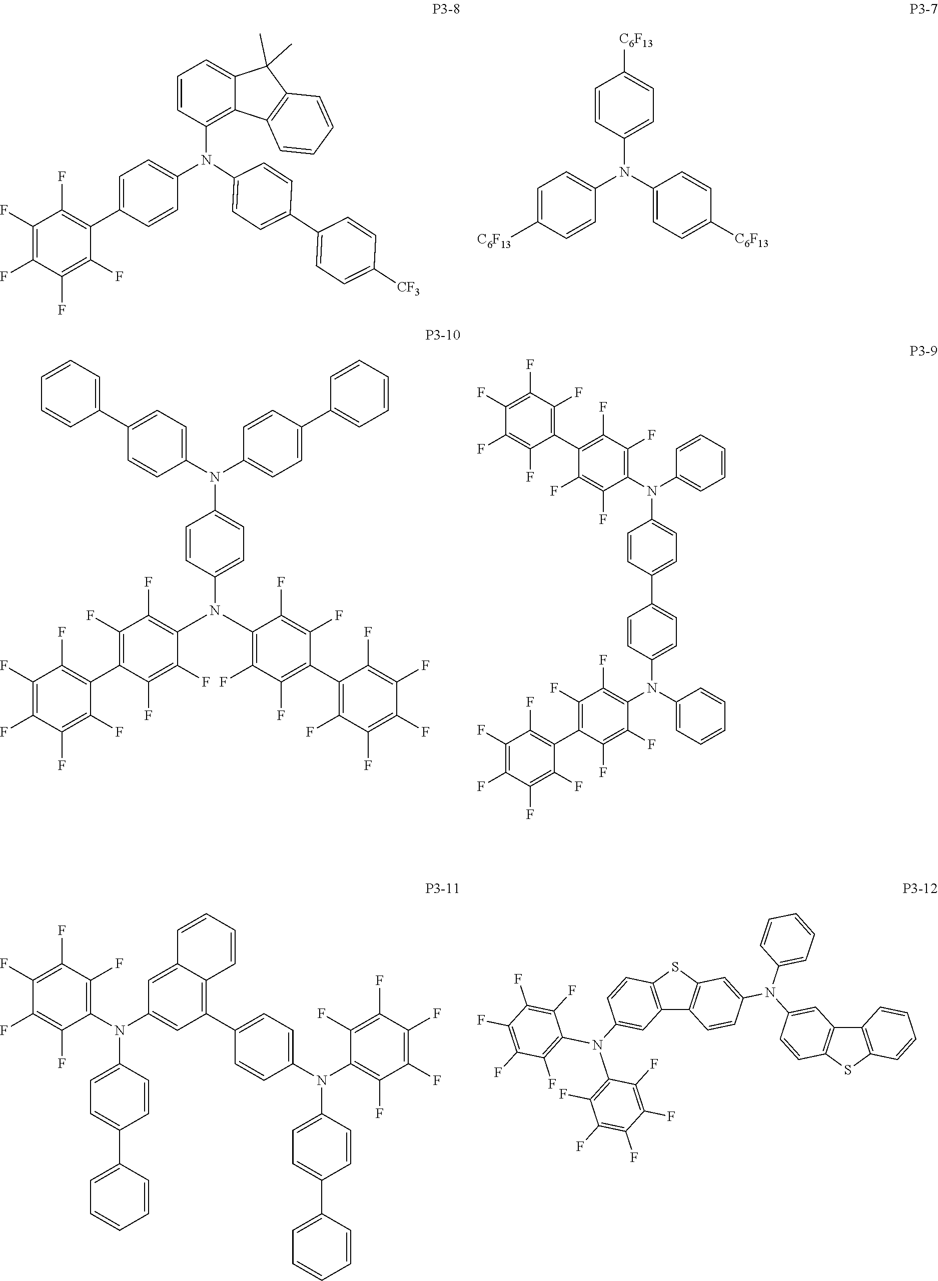

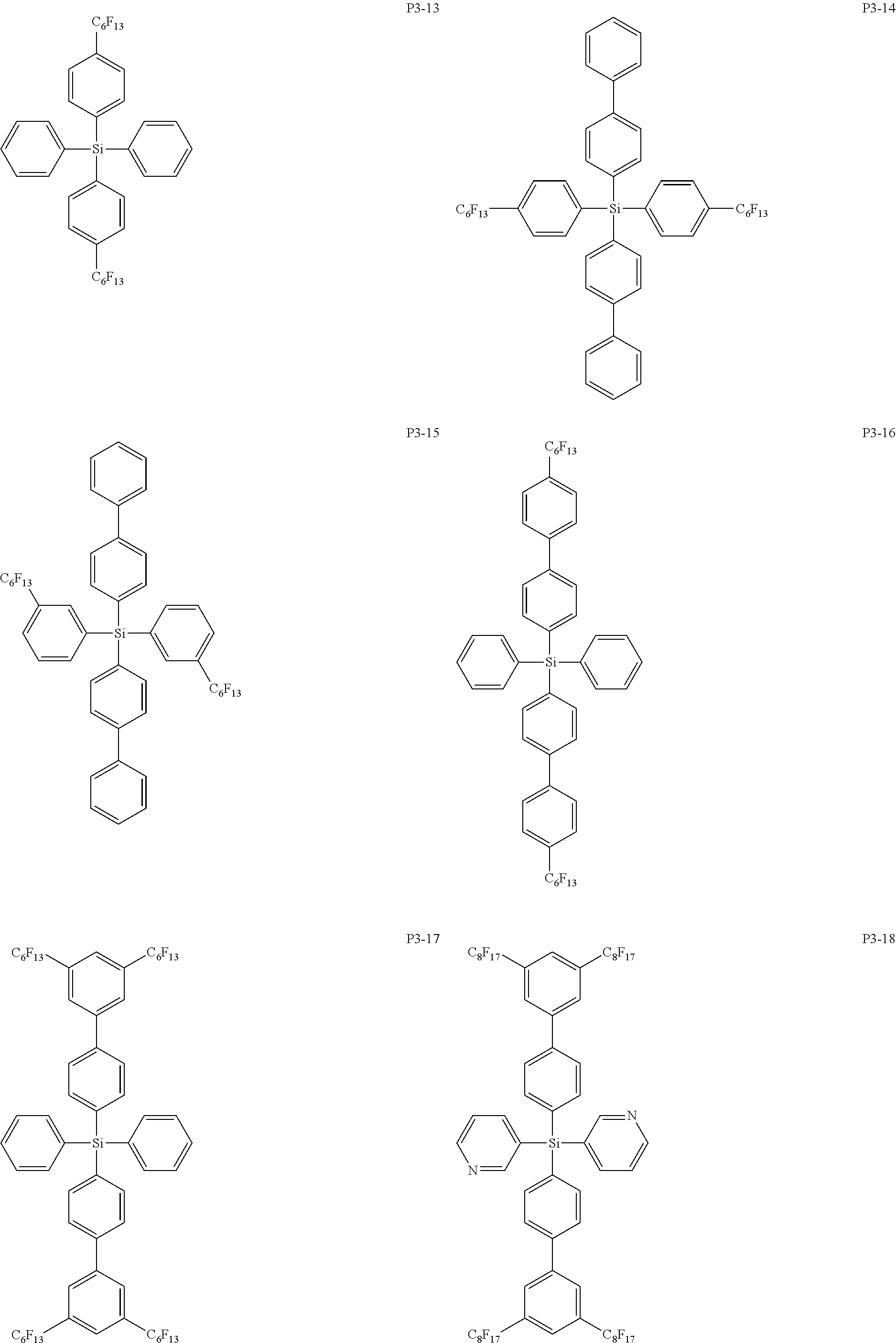

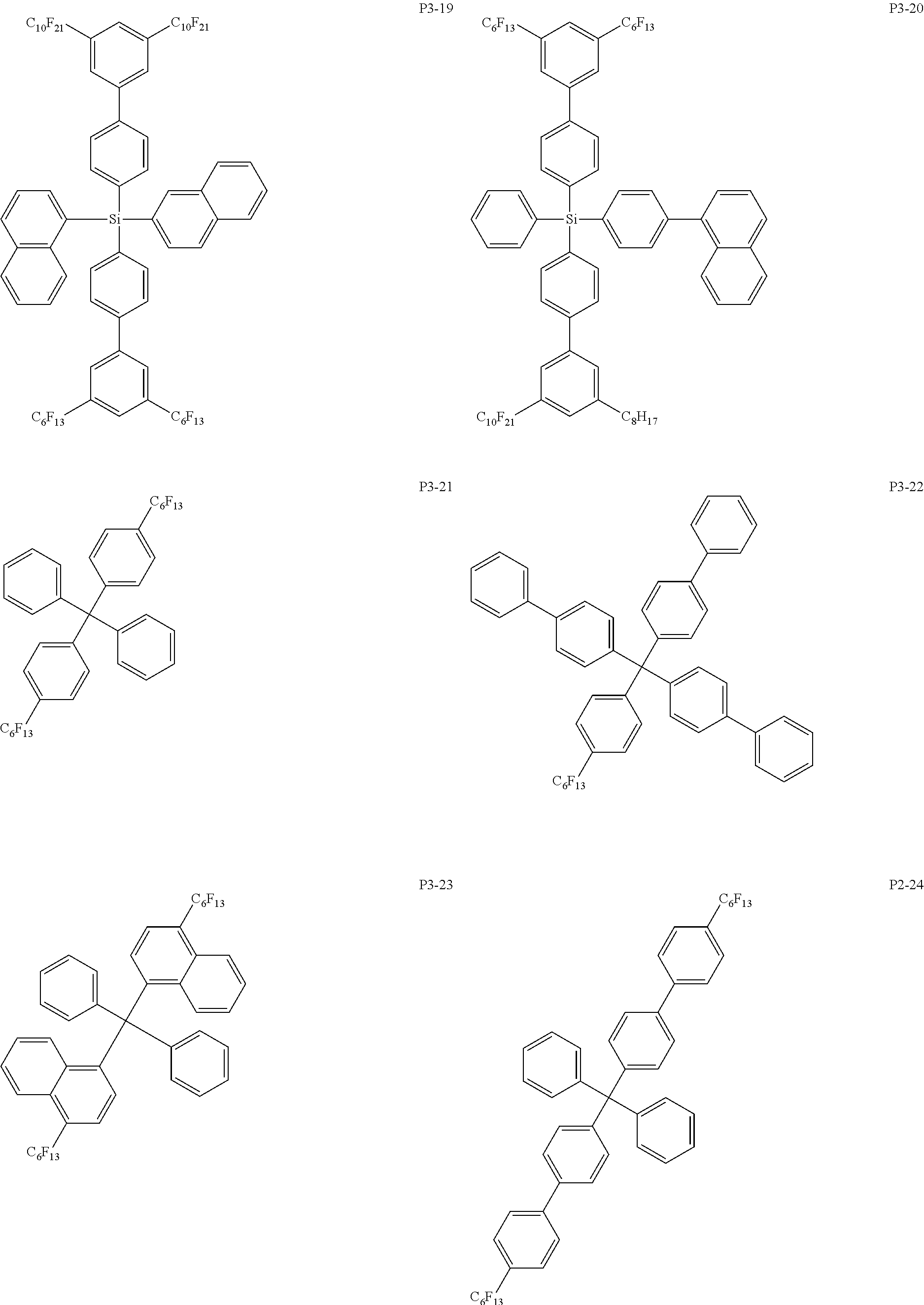

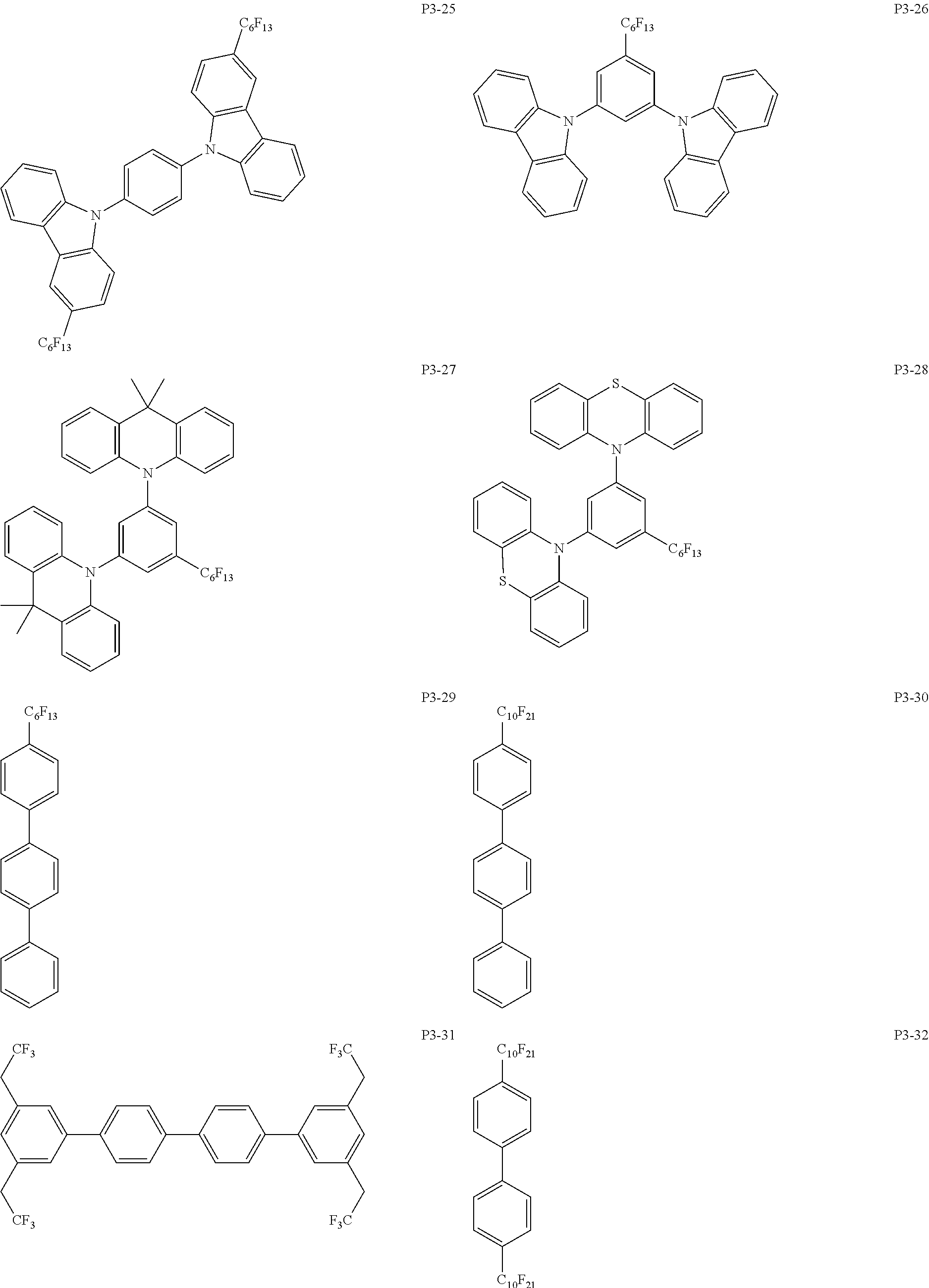

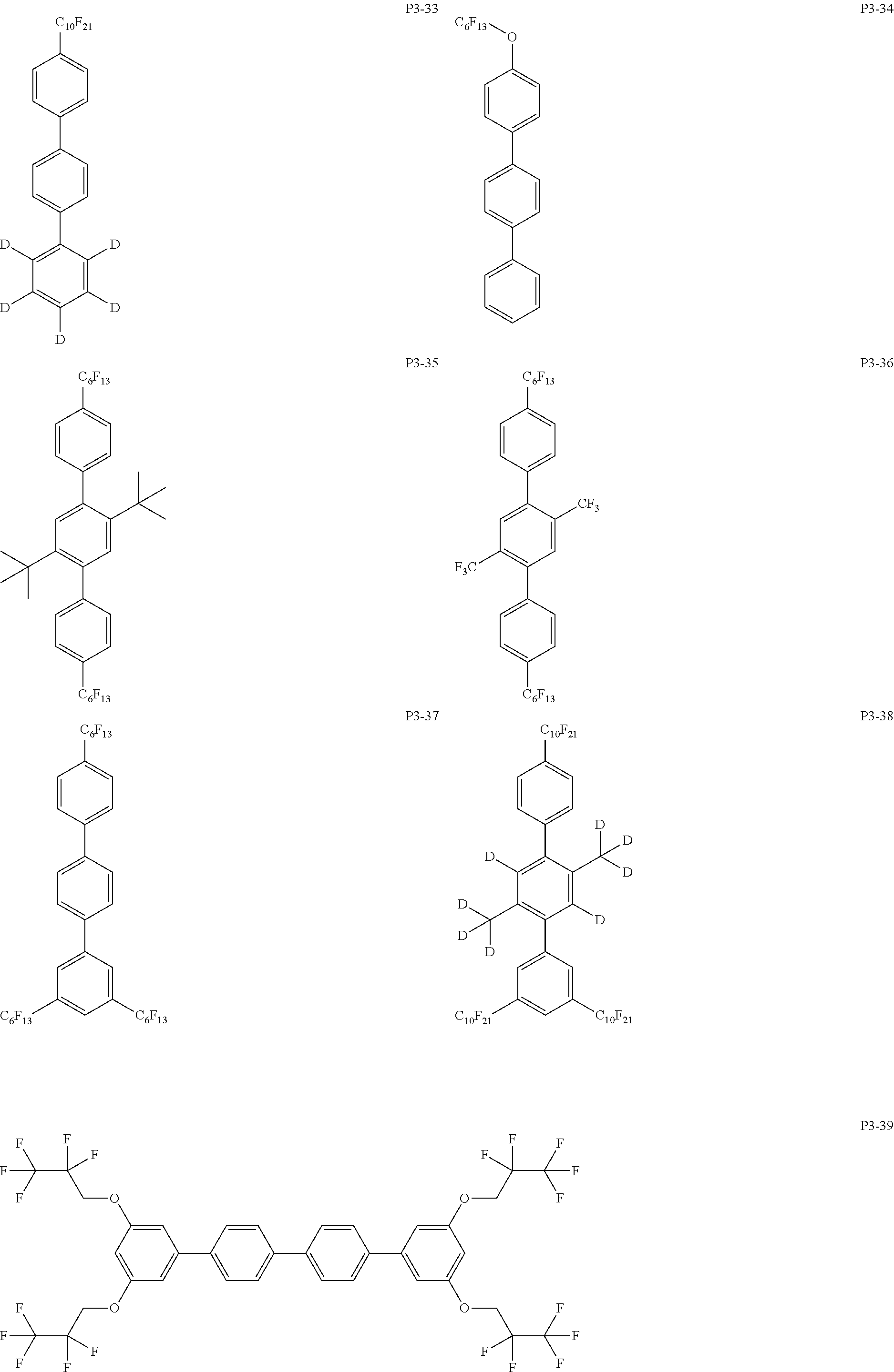

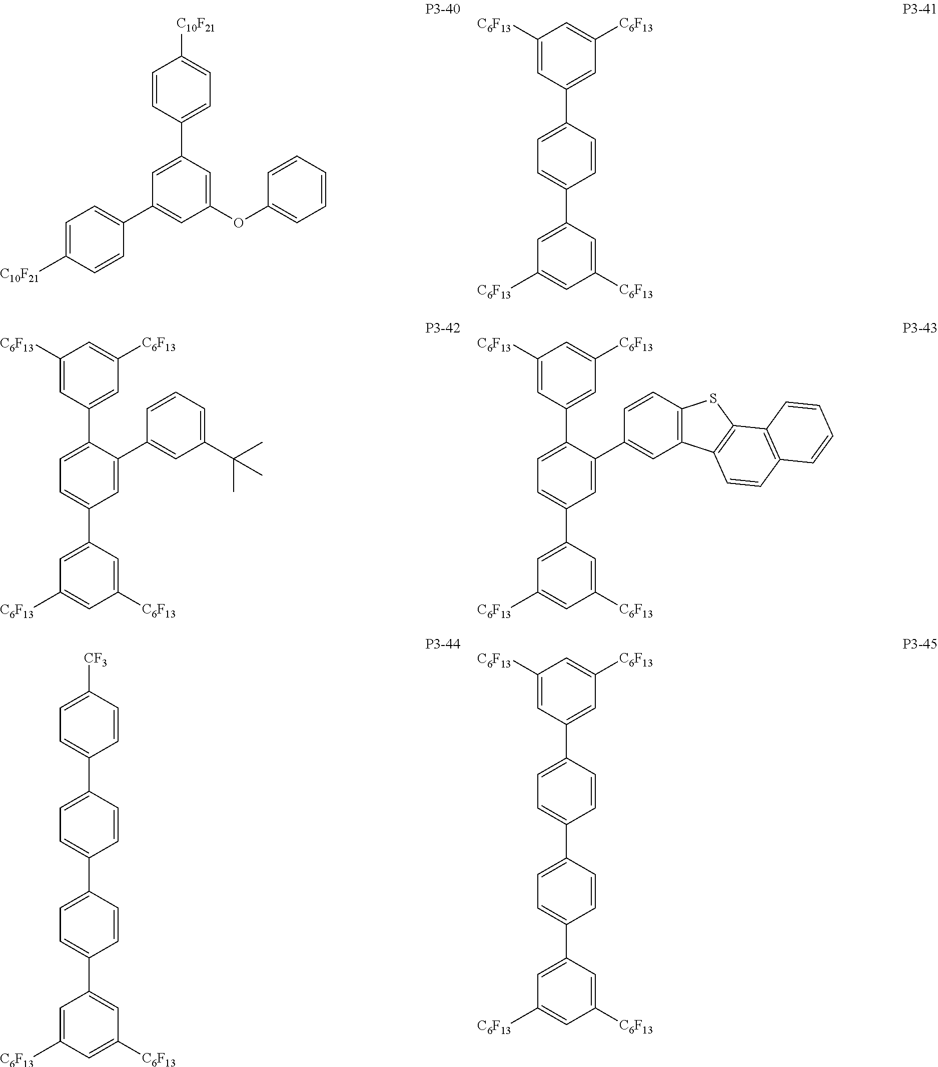

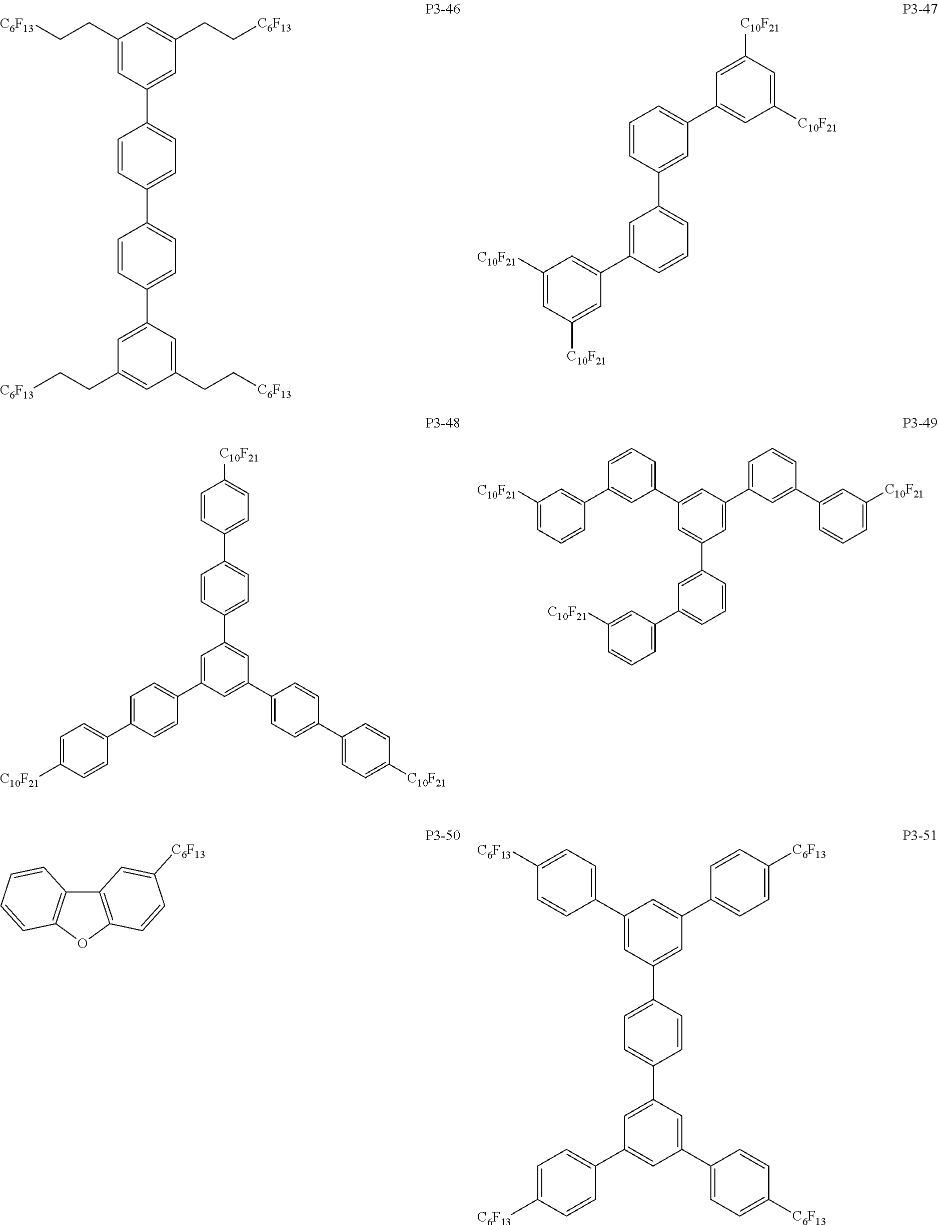

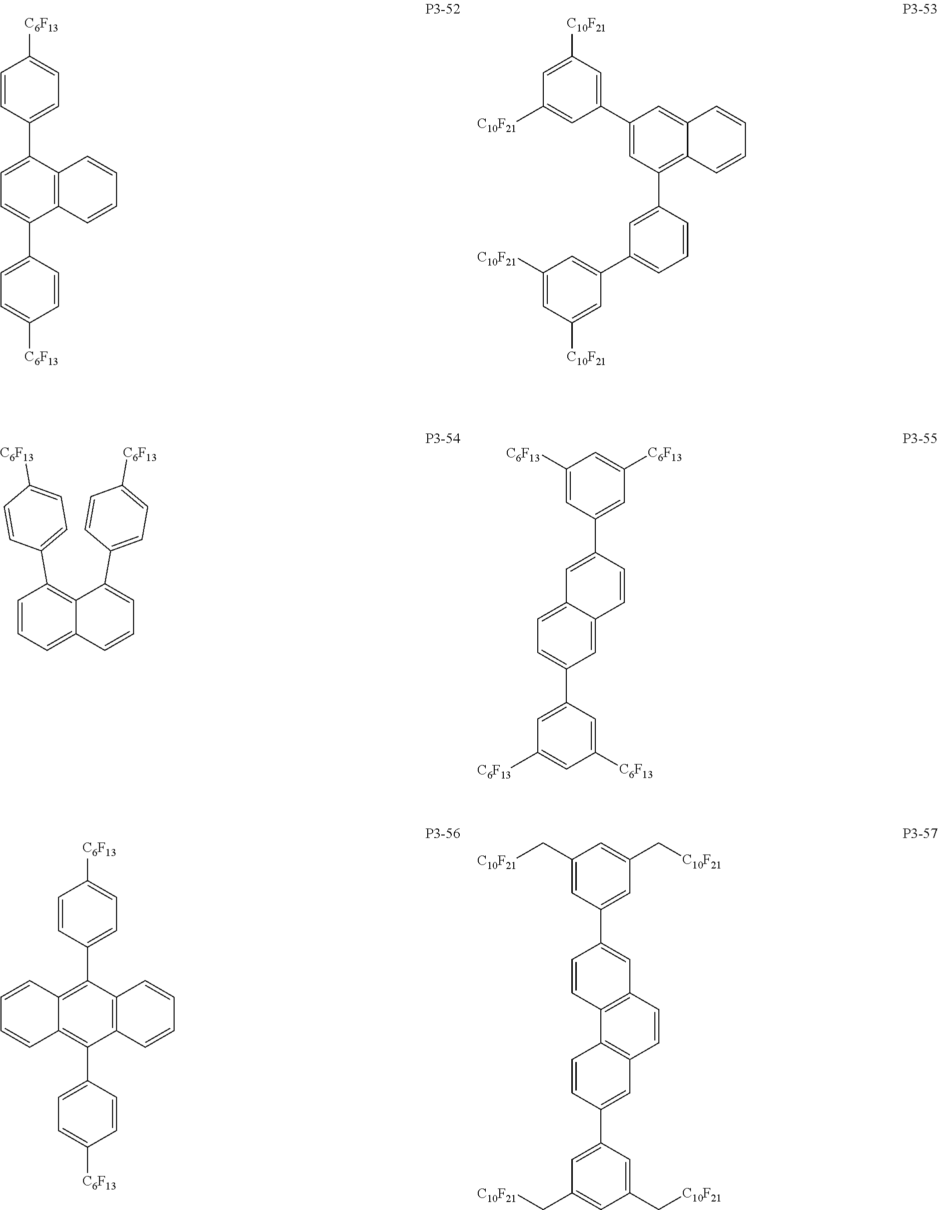

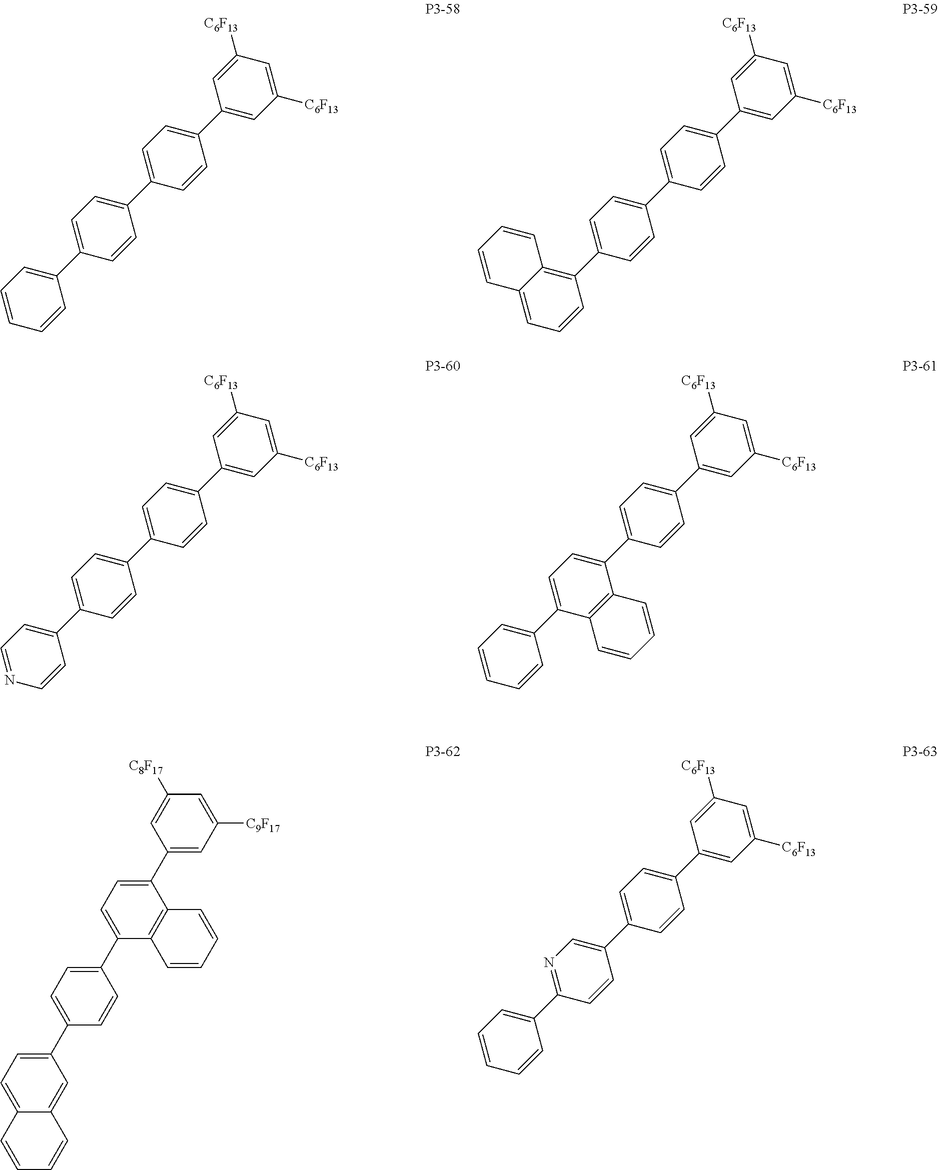

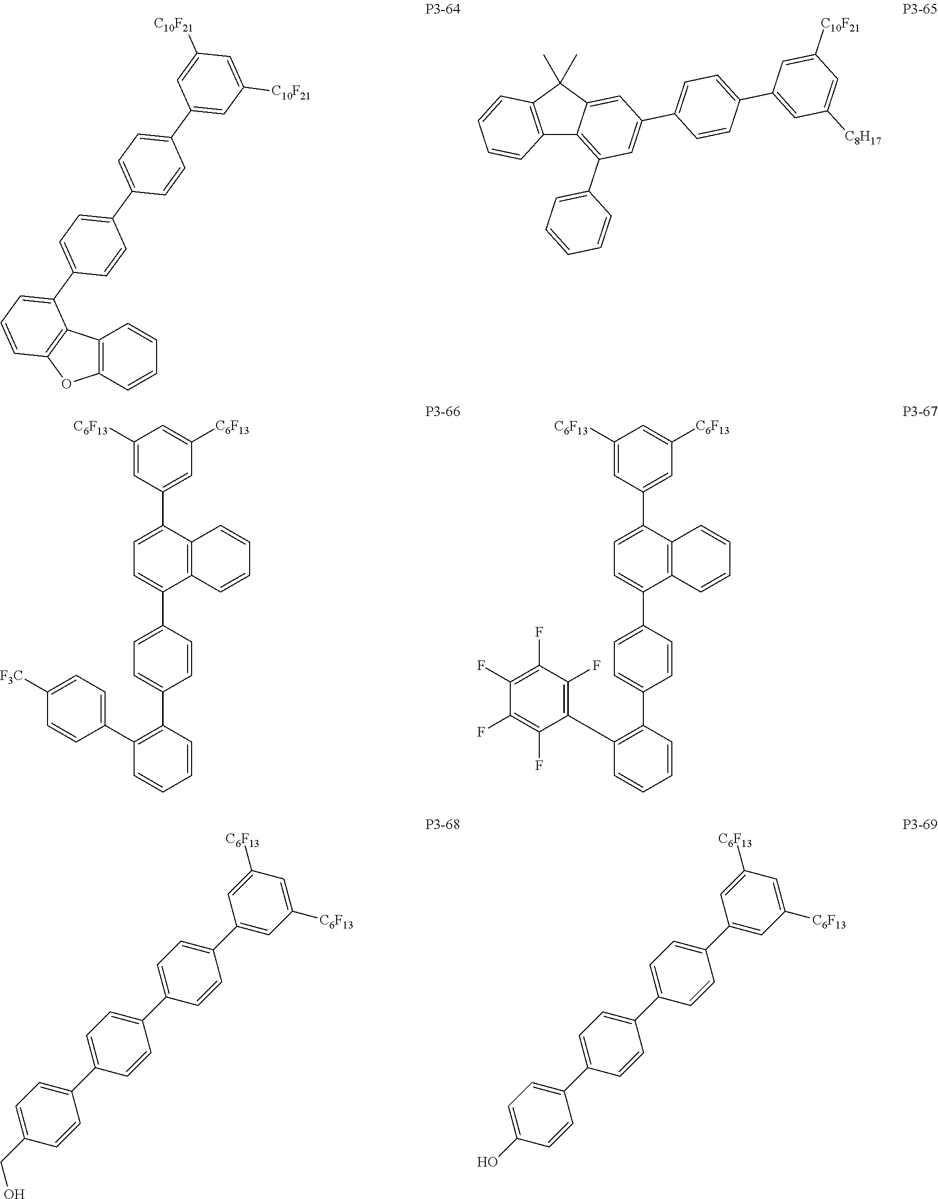

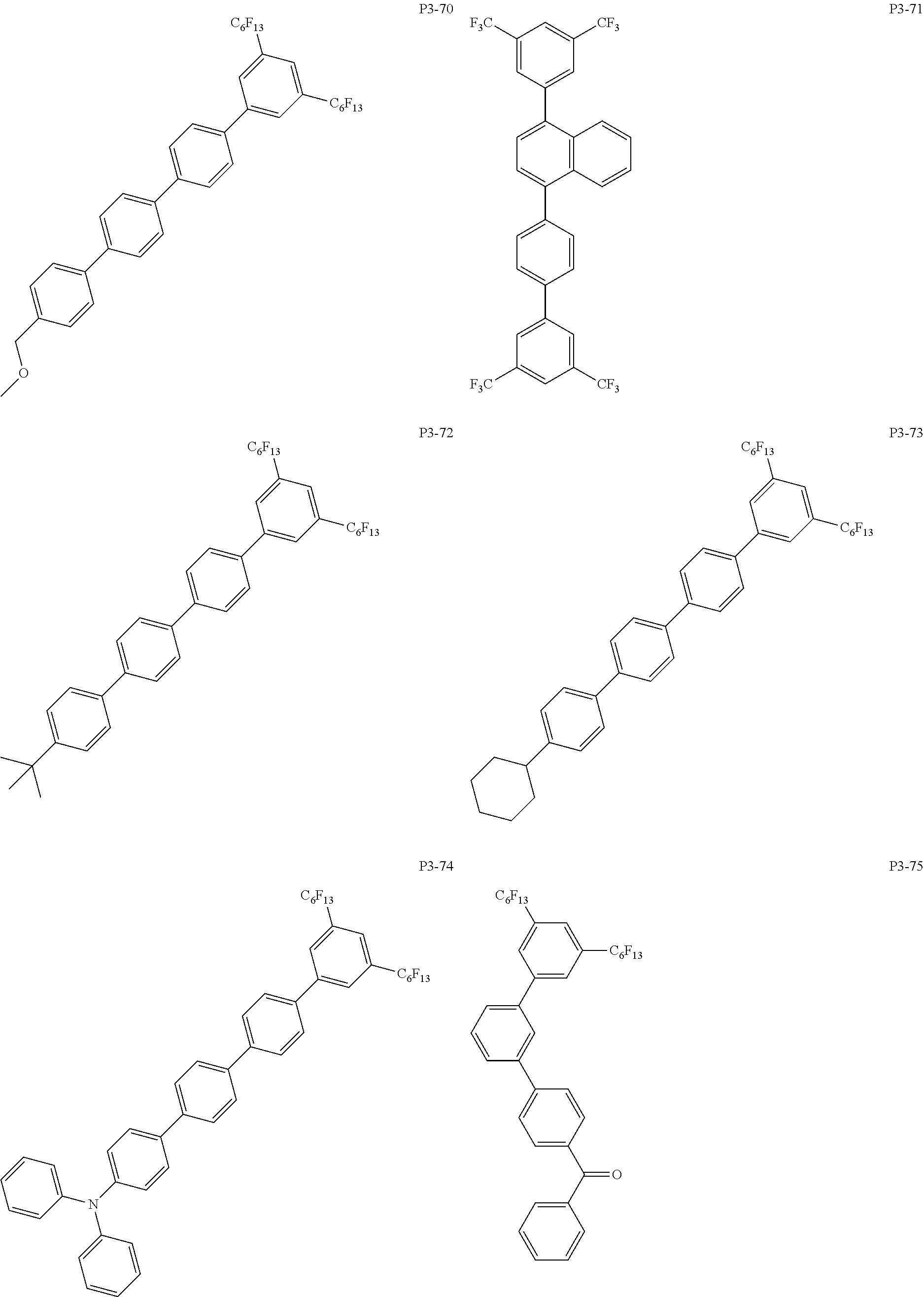

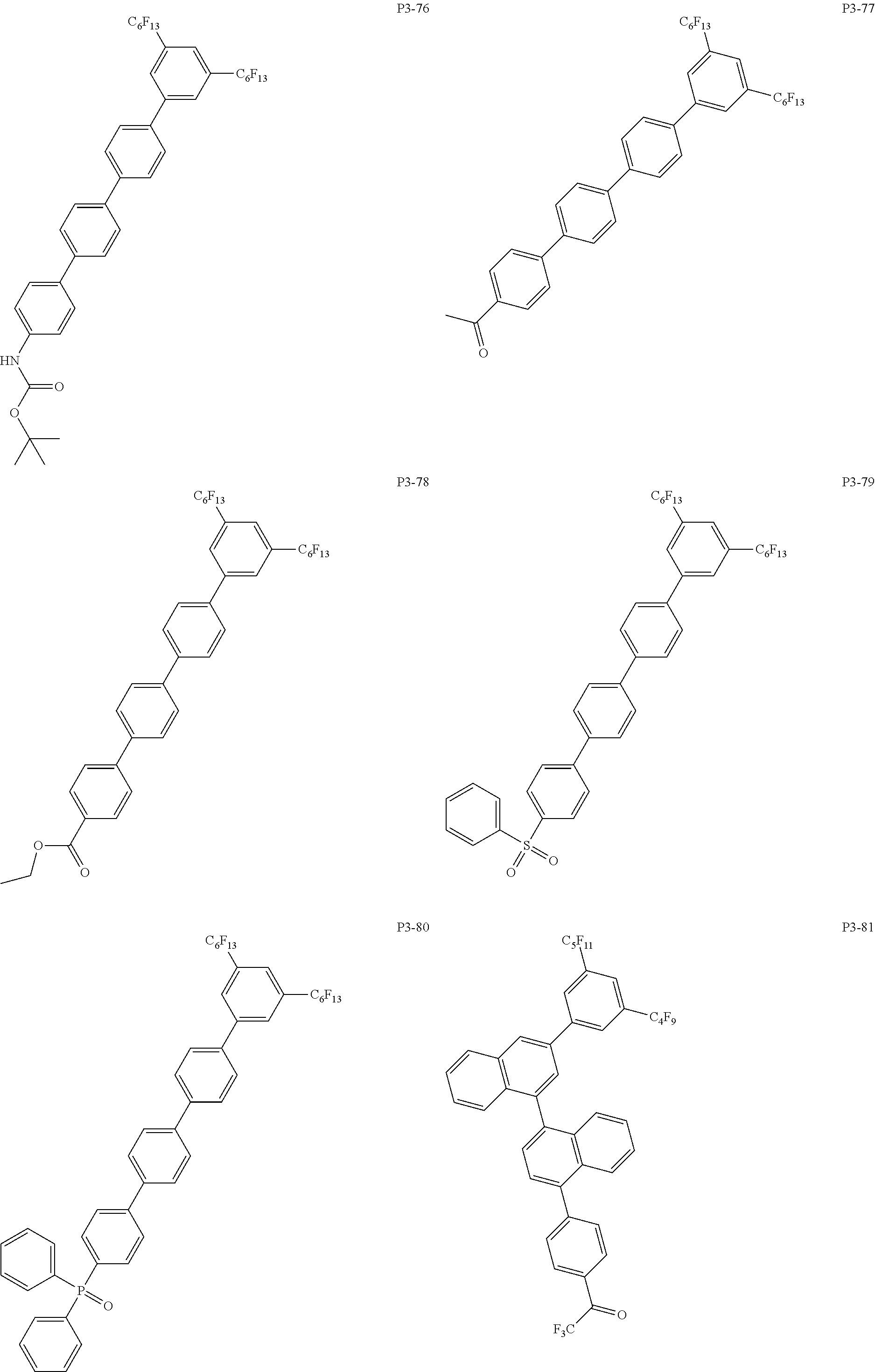

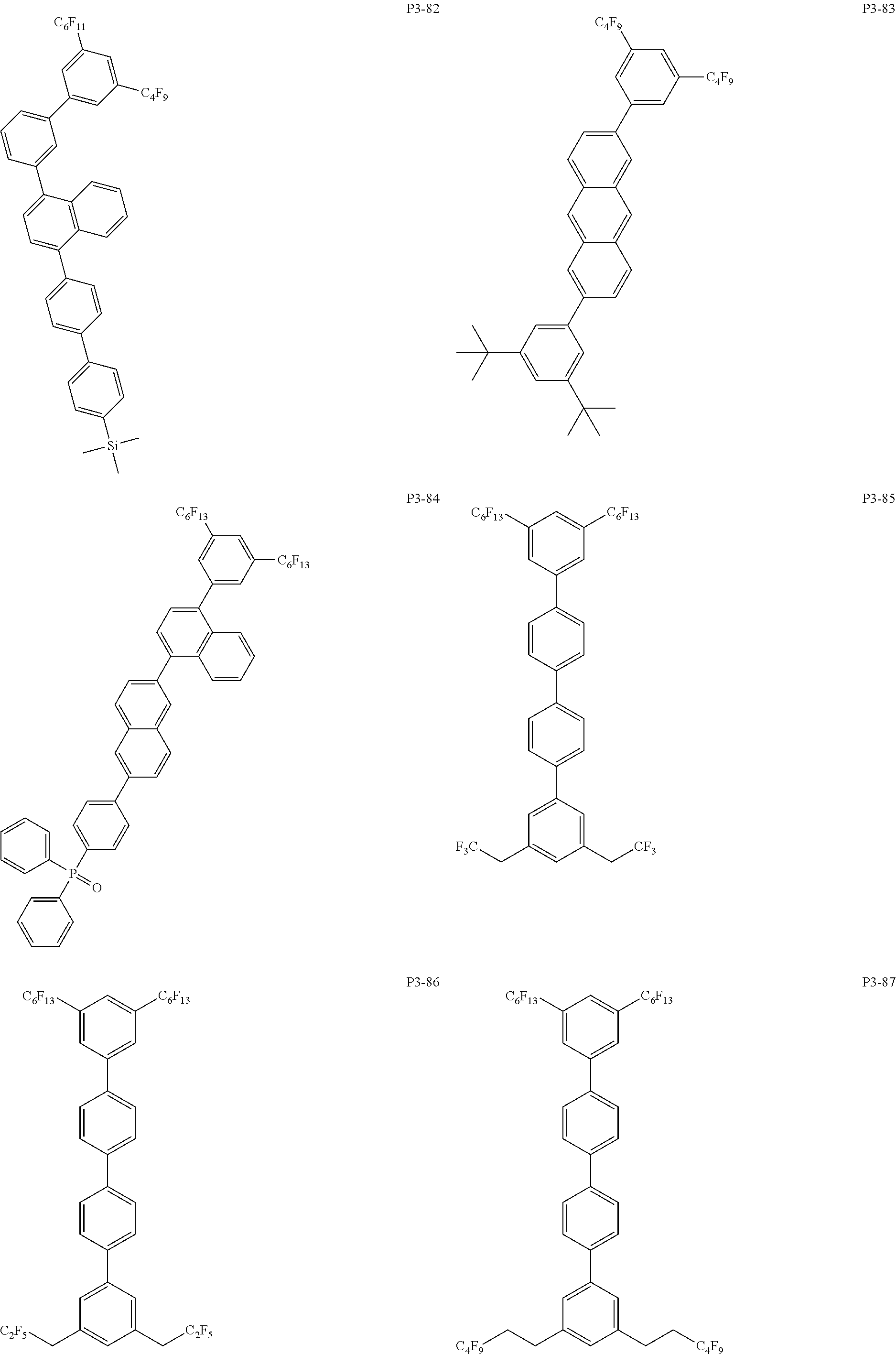

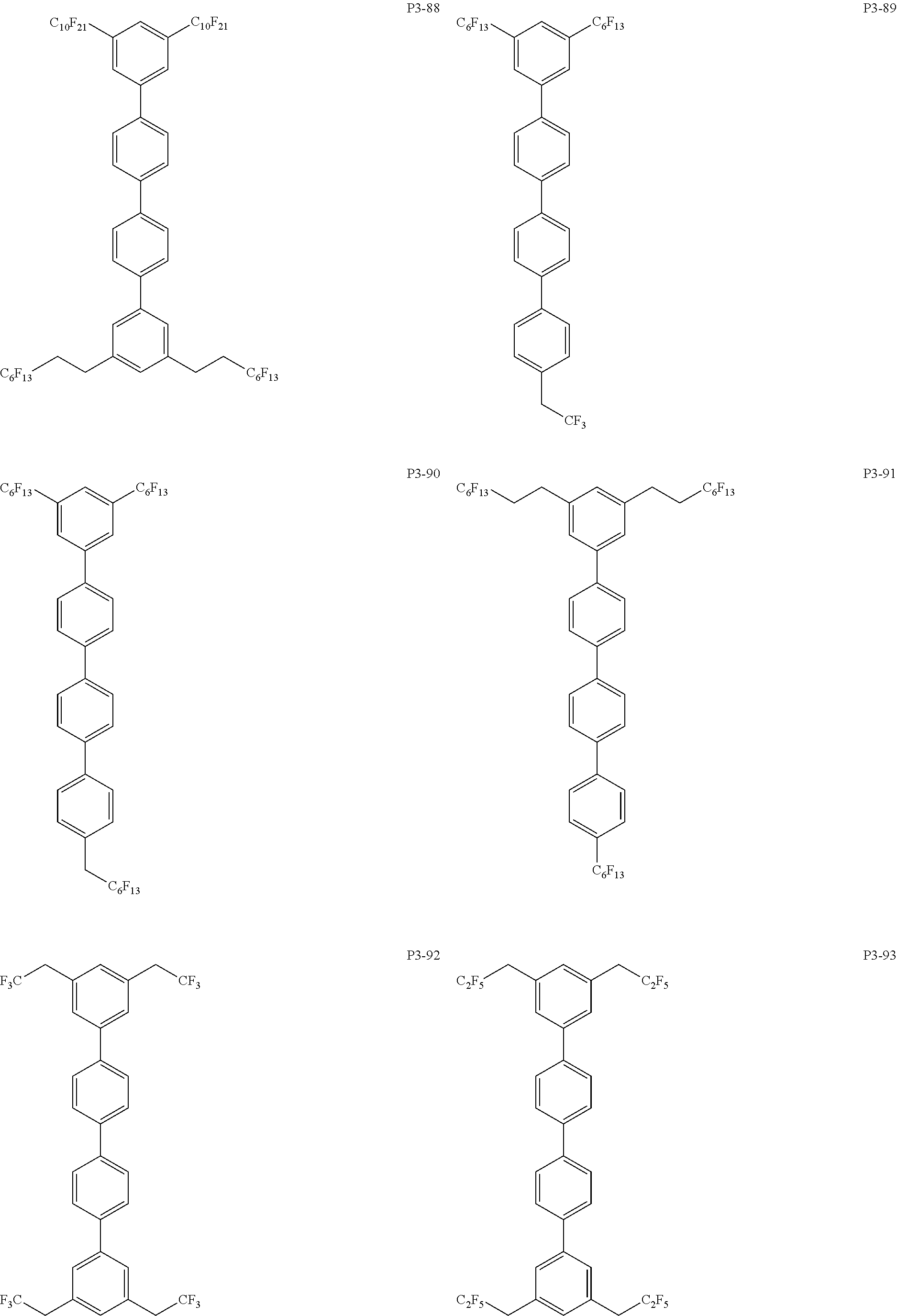

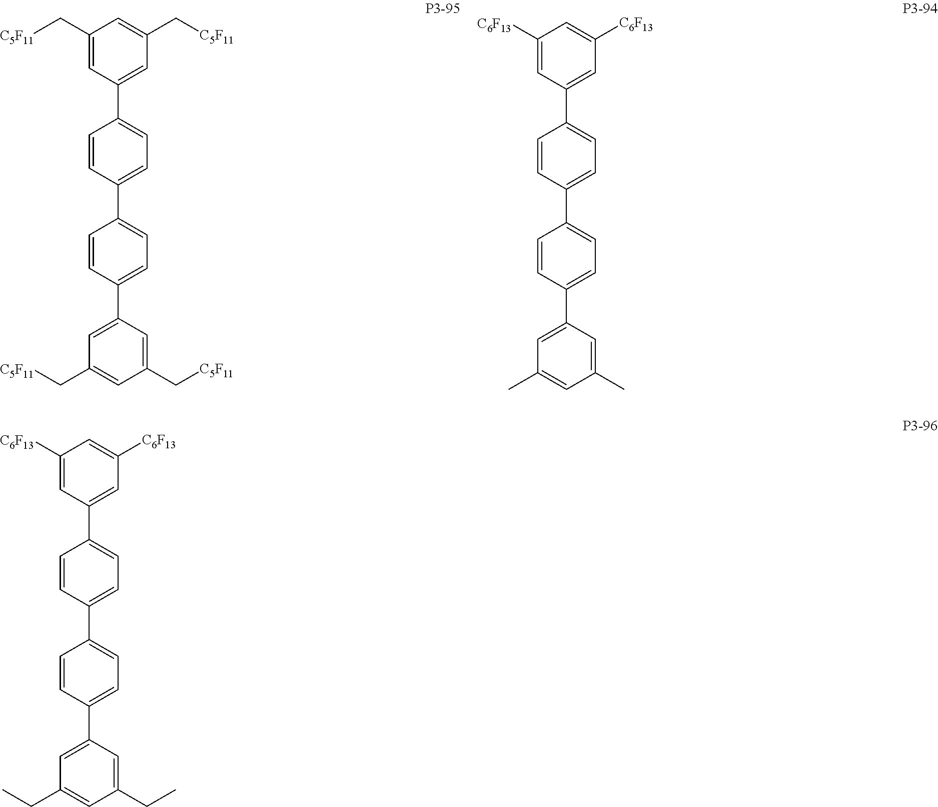

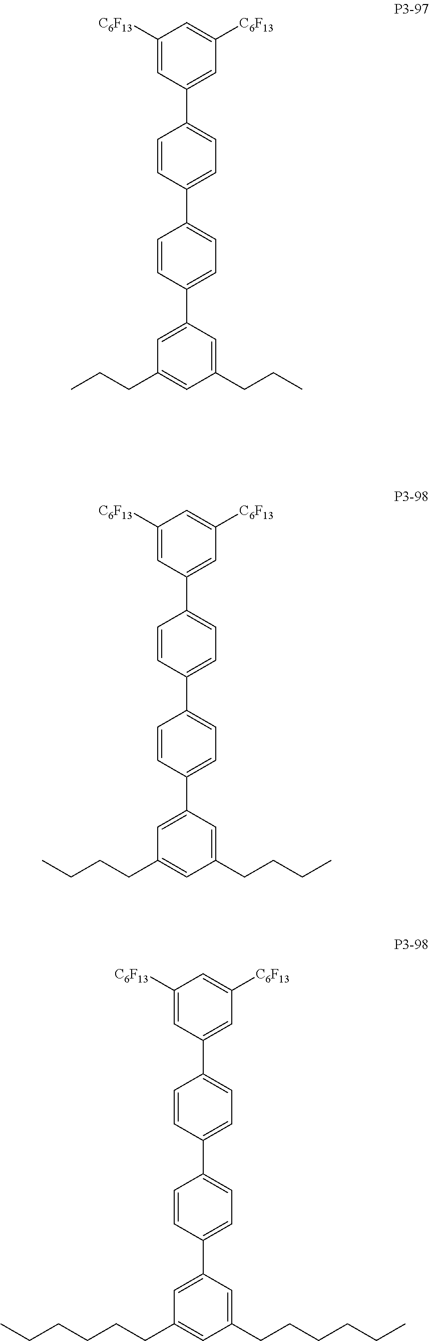

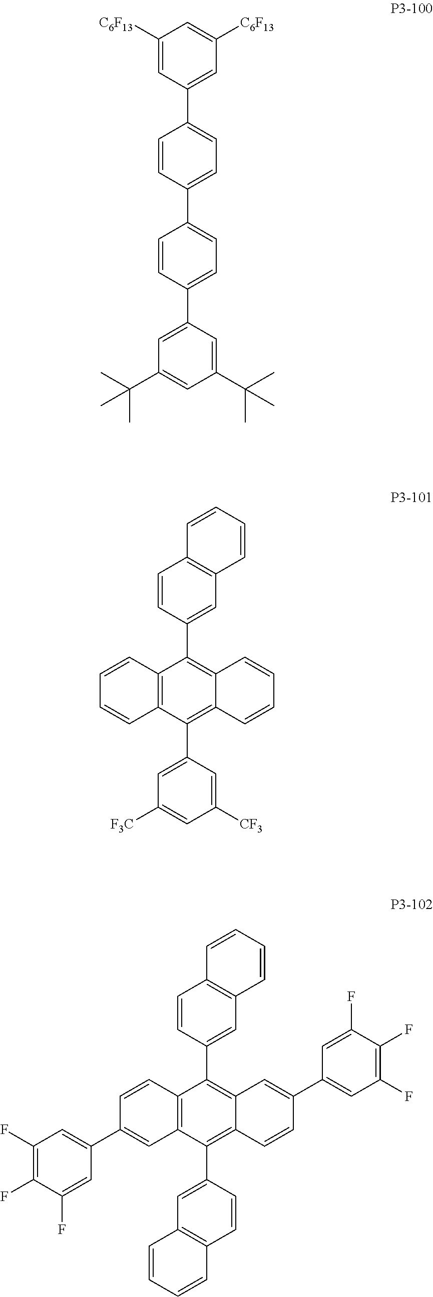

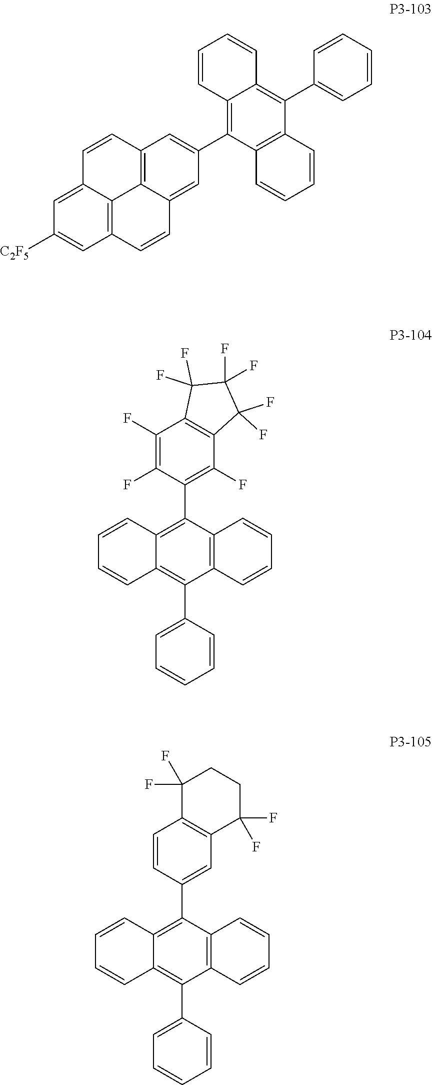

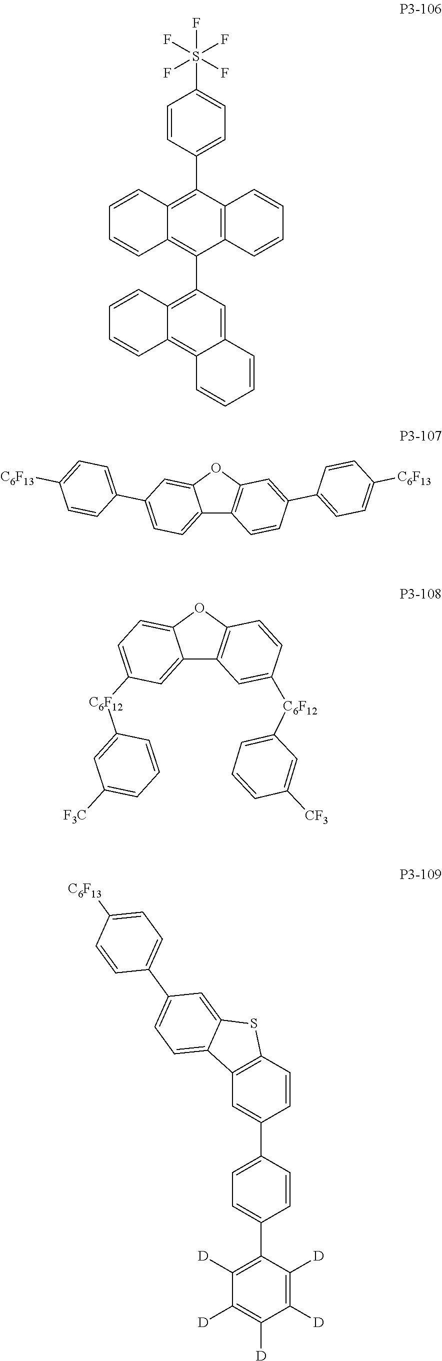

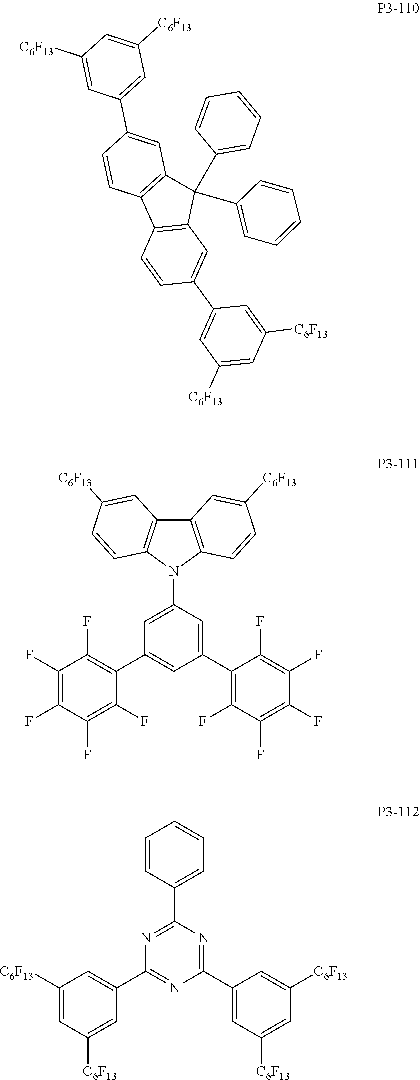

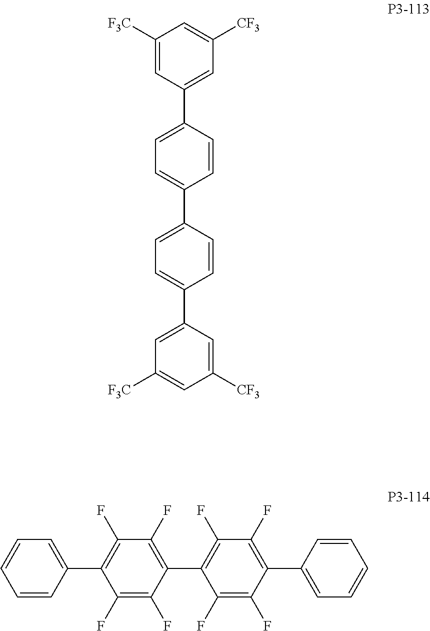 [SMILES: FC(F)(F)c1cc(-c2ccc(-c3ccc(-c4cc(C(F)(F)F)cc(C(F)(F)F)c4)cc3)cc2)cc(C(F)(F)F)c1 ; Fc1c(F)c(-c2c(F)c(F)c(-c3ccccc3)c(F)c2F)c(F)c(F)c1-c1ccccc1]

Hereinafter, examples of synthesis of the compound represented by Formula A of the present invention and examples of manufacturing the organic electronic element of the present invention will be described in detail by way of examples, but the present invention is not limited to the following examples.

### Synthesis Example of Formula A

### 1. Synthesis Example of P3-13

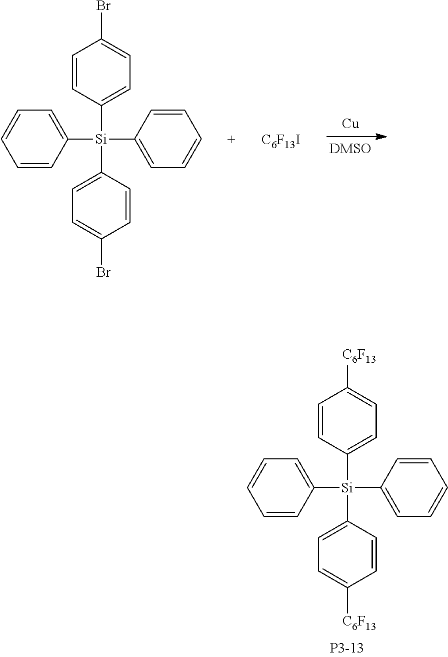

Bis(4-bromophenyl)diphenylsilane (3.0 g, 6.07 mmol), Cu (3.1 g, 48.6 mmol) and DMSO (12 mL) were added to a round bottom flask, dissolved at 70° C., and stirred for 30 minutes. After that, perfluorohexyl iodide (6.0 g, 13.4 mmol) was slowly added dropwise over 1 hour and stirred at 120° C. for 24 hours. After the reaction was completed, distilled water was added and the resulting solid was filtered under reduced pressure. After that, the filtrate was extracted using ethyl acetate, the organic layer was dried with MgSO₄ and concentrated, and the resulting compound was separated using a silica gel column and recrystallized to obtain 4.4 g of the product (yield: 75%).

### 2. Synthesis Example of P3-26

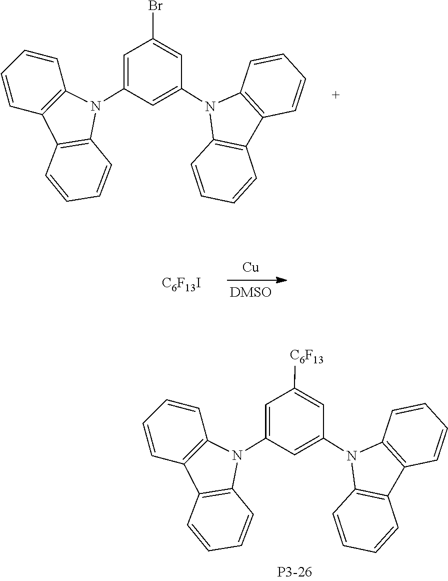

9,9′-(5-bromo-1,3-phenylene)bis(9H-carbazole) (3.0 g, 6.16 mmol), Cu (3.1 g, 49.2 mmol), Perfluorohexyl iodide (3.0 g, 6.77 mmol) and DMSO (12 mL) were used to obtain 3.2 g (yield: 72%) of the product through the synthetic method of P3-13.

### 3. Synthesis Example of P3-30

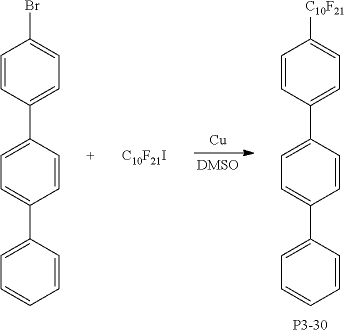

4-bromo-1,1′:4′,1″-terphenyl (3.0 g, 9.70 mmol), Cu (4.9 g, 77.6 mmol), Perfluorodecyl iodide (6.9 g, 10.7 mmol) and DMSO (19 mL) were used to obtain 5.1 g (yield: 70%) of the product through the synthetic method of P3-13.

Meanwhile, an exemplary synthesis example of the present invention represented by Formula A has been described above, but these are all based on the Buchwald-Hartwig cross coupling reaction, Miyaura boration reaction, Suzuki cross-coupling reaction, Intramolecular acid-induced cyclization reaction (J. mater. Chem. 1999, 9, 2095), Pd(II)-catalyzed oxidative cyclization reaction (Org. Lett. 2011, 13, 5504), and PPh₃-mediated reductive cyclization reaction (J. Org. Chem. 2005, 70, 5014), and those skilled in the art will easily understand that the above reaction proceeds even if other substituents defined in Formula A are bonded to, other than the substituent specified in the specific synthetic example.

### Comparison of Light Transmittance According to the Thickness of Metal Patterning Layer and Metal Electrode

In Examples 1 to 5 and Comparative Examples 1 and 2, the thickness of the metal patterning layer was fixed, and the thickness of the metal electrode was varied to measure the light transmittance of the element accordingly.

The samples were prepared in a high-vacuum deposition system having a cryo-pumped processing chamber and a turbo-molecular pumped loadlock chamber using a stainless steel shadow mask. The materials were thermally deposited from a Knudsen cell (K-cell) using a quartz crystal microbalance (QCM) to monitor the deposition rate. The base pressure of the system was less than approximately 10⁻⁵ Pa, and the partial pressure of H₂O was less than approximately 10⁻⁸ Torr during deposition. Ag was deposited at a source temperature of approximately 1020-1050° C. with a deposition rate of approximately 0.9 Å/sec.

Metal Ag was deposited in various thicknesses on the prepared bare glass, and an open mask was used during deposition to form a thin film over the entire bare glass. All deposition processes were performed under vacuum (e⁻⁸ torr), and the total thickness and deposition rate were monitored using a calibrated QCM.

### Example 1

First, a N-([1,1′-biphenyl]-4-yl)-9,9-dimethyl-N-(4-(9-phenyl-9H-carbazol-3-yl)phenyl)-9H-fluoren-2-amine (hereinafter abbreviated as C-1) film was vacuum-deposited as an organic layer on a glass substrate to form a thickness of 1000 Å. A metal patterning layer was formed by vacuum-depositing the compound P3-59 of the present invention on the organic layer to a thickness of 150 Å. Next, the QCM used in the deposition of the compound of the present invention was mounted on one of the Dual Sensors of the Metal Chamber, and a new QCM was mounted on the other one, and then a metal electrode (cathode) of 100 Å of Ag was deposited on the metal patterning layer.

### [Example 2] to [Example 5]

A sample was manufactured in the same manner as in Example 1, except that the thickness of the metal electrode was deposited as shown in Table 1.

Additionally, the light transmittance sample of the manufactured example was measured for the light transmittance in the visible light range of 450 nm, 550 nm, and 630 nm using a Lambda 365 LVNIS Spectrometer from Perkinelmer, and the measurement results are shown in Table 1.

### [Comparative Example 1] and [Comparative Example 2]

A light transmittance sample was produced in the same manner as in Example 1, except that the thickness of the metal electrode was deposited as shown in Table 1.

TABLE 1

| | Thickness | thickness | | | |
|---|---|---|---|---|---|
| | of the | of the | | | |
| | metal | metal | 450 nm | 530 nm | 630 nm |
| | patterning | electrode | Transmit- | Transmit- | Transmit- |
| | layer (Å) | (Å) | tance (%) | tance (%) | tance (%) |
| Comparative | 150 | 300 | 76.73 | 78.89 | 78.01 |
| example 1 | | | | | |
| Comparative | 150 | 150 | 79.67 | 81.13 | 80.51 |
| example 2 | | | | | |
| example 1 | 150 | 100 | 91.07 | 90.64 | 90.04 |
| example 2 | 150 | 80 | 93.86 | 92.04 | 91.29 |
| example 3 | 150 | 70 | 96.01 | 95.06 | 95.95 |
| example 4 | 150 | 60 | 97.29 | 96.09 | 97.78 |
| example 5 | 150 | 50 | 98.72 | 98.58 | 98.19 |

As can be seen at the results in Table 1, it can be seen that the light transmittance of the element of Comparative Example 2, in which the thickness of the metal patterning layer and the thickness of the metal electrode were deposited identically, slightly increased compared to Comparative Example 1, in which the thickness of the metal patterning layer was deposited thinner than the thickness of the metal electrode, and that the light transmittance of the elements of Examples 1 to 5, in which the metal patterning layer was deposited thicker than the metal electrode, significantly improved compared to Comparative Example 2.

These results show that when the thickness of the metal patterning layer is thinner than the thickness of the metal electrode or when the thicknesses of the metal patterning layer and the metal electrode are the same, the metal deposition hindrance effect of the metal patterning layer is not properly expressed, which results in some metal accumulating on the metal patterning layer, thereby reducing the light transmittance.

However, examples 1 to 5 in which the metal patterning layer was deposited thicker than the metal electrode showed a light transmittance exceeding 90%. This is because the metal patterning layer was deposited thicker than the metal electrode, and thus the metal deposition hindrance effect of the metal patterning layer was maximized, and thus the metal was not accumulated on the metal patterning layer, thereby improving the light transmittance. That is, the thickness of the metal patterning layer must be deposited thicker than the thickness of the metal electrode to enable precise patterning of the metal electrode (cathode) and improve the transmittance of the organic electronic element.

### Comparison of Light Transmittance According to Material of Metal Patterning Layer

### Comparative Example 3

A light transmittance sample was produced in the same manner as in Example 5, except that Comparative compound 1 was used instead of the compound P3-59 of the present invention as a metal patterning layer material, and Ag was deposited as a metal electrode (cathode) with a thickness of 50 Å.

### <Comparative Compound 1>

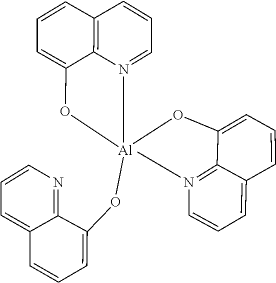

### [Example 6] to [Example 11]

A light transmittance sample was prepared in the same manner as in Example 5, except that the compound of the present invention described in Table 2 was used instead of the compound P3-59 of the present invention as the metal patterning layer material.

The light transmittance samples of Examples 6 to 11 and Comparative Example 3 manufactured in this manner were measured for light transmittance at 450 nm in the visible light range using a Lambda 365 UVNIS Spectrometer measuring device from Perkinelmer, and the measurement results are shown in Table 2.

The fluorine content of the compounds described in Table 2 is expressed by Equation (A).

Fluorine content=number of fluorine atoms in the compound/total number of atoms in the compound×100 [Equation (A)]
wherein, the number of fluorine atoms in a compound refers to the number of fluorine atoms contained in the compound, and the total number of atoms in a compound refers to the total number of atoms in the compound comprising fluorine.

TABLE 2

| | Metal patterning layer | | 450 nm light |
|---|---|---|---|
| | material | F ratio (%) | transmittance (%) |
| Comparative | Comparative | 0 | 64.12 |
| example3 | compound 1 | | |
| example6 | P3-31 | 18.18 | 96.43 |
| example7 | P3-39 | 24.39 | 98.50 |
| example8 | P3-50 | 45.61 | 98.31 |
| example9 | P3-86 | 37.50 | 98.62 |
| example10 | P3-70 | 30.59 | 98.93 |
| example11 | P3-114 | 19.05 | 97.51 |

At the results in Table 2, in the case of Comparative Example 3, a metal patterning layer was formed with Comparative Compound 1, but it can be seen that the metal deposition hindrance effect of Comparative Compound 1 was low, so metal was accumulated on the metal patterning layer and the light transmittance was low. As a result, the results of Examples 6 to 11 show that the metal deposition inhibition effect is improved when a fluorinated material is used, and that precise patterning of the metal electrode (cathode) is easy.

Although exemplary embodiments of the present invention have been described for illustrative purposes, those skilled in the art will appreciate that various modifications, additions and substitutions are possible, without departing from the scope and spirit of the invention as disclosed in the accompanying claims. Therefore, the embodiment disclosed in the present invention is intended to illustrate the scope of the technical idea of the present invention, and the scope of the present invention is not limited by the embodiment.

The scope of the present invention shall be construed on the basis of the accompanying claims, and it shall be construed that all of the technical ideas included within the scope equivalent to the claims belong to the present invention.

### DESCRIPTION OF THE NUMERALS

100: Anode
110: First part
111: Organic material layer
112: Hole injection layer
113: Hole transport layer
114: Emitting layer
115: Electron transport layer
116: Electron injection layer
117: Patterning auxiliary photosensitive layer
118: Cathode
120: Second part
121: Metal patterning layer
122: Emitting auxiliary layer
123: Hole blocking layer
124: First emitting auxiliary layer
125: Second emitting auxiliary layer
130: Third part

What is claimed is:

1. An organic electronic element comprising:
a substrate and an anode disposed on the substrate,
wherein a first part as an emitting area and a second part as a transmission area are on the anode,
wherein the first part and second part comprise an organic material layer formed in common,
wherein the organic material layer comprises a hole transport layer, an emitting layer, and an electron transport layer,
wherein a metal electrode is on the organic material layer of the first part,
wherein a metal patterning layer is on the organic material layer of the second part, and
wherein the metal patterning layer is formed thicker than the thickness of the metal electrode.

2. The organic electronic element according to claim 1, wherein the thickness of the metal patterning layer is formed to be at least twice that of the metal electrode.

3. The organic electronic element according to claim 1, wherein the thickness of the metal patterning layer is 100 Å to 300 Å.

4. The organic electronic element according to claim 1, wherein the metal patterning layer material comprises at least one fluorine (F) in the molecule.

5. The organic electronic element according to claim 1, wherein the metal patterning layer material comprises a compound represented by Formula A: 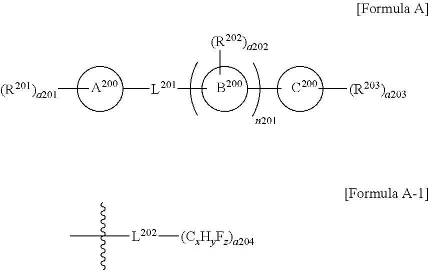
wherein:
A²⁰⁰ ring, B²⁰⁰ ring and C²⁰⁰ ring are independently a C₆-C₆₀ aryl group; or a C₂-C₆₀ heteroaryl group including at least one heteroatom of O, N, S, Si or P;
L²⁰¹ is selected from the group consisting of a single bond; NR²⁰⁴; CR²⁰⁴R²⁰⁵;
SiR²⁰⁴R²⁰⁵; a fluorinated C₁-C₆₀ alkylene group; and a fluorinated C₂-C₂₀ alkenylene group;
L²⁰² is selected from the group consisting of a single bond; a C₁-C₆₀ alkylene group; a C₂-C₂₀ alkenylene group; a C₂-C₂₀ alknylene group; a C₁-C₃₀ alkoxylene group; a C₆-C₆₀ aryloxylene group; a C₆-C₆₀ arylene group; a fluorenylene group; a C₂-C₃₀ heterocyclic group including at least one heteroatom of O, N, S, Si or P; and a fused ring group of a C₃-C₆₀ aliphatic ring and a C₆-C₆₀ aromatic ring;
R²⁰¹, R²⁰² and R²⁰³ are each independently the same or different, and each independently selected from the group consisting of hydrogen; deuterium; halogen; a C₆-C₆₀ aryl group; a fluorenyl group; a C₂-C₆₀ heterocyclic group including at least one hetero atom of O, N, S, Si or P; a fused ring group of a C₃-C₆₀ aliphatic ring and an C₆-C₆₀ aromatic ring; a C₁-C₆₀ alkyl group; a C₂-C₂₀ alkenyl group; a C₂-C₂₀ alkynyl group; a C₁-C₃₀ alkoxyl group; a C₆-C₆₀ aryloxy group; and a substituent represented by Formula A-1, provided that at least one of R²⁰¹, R²⁰² and R²⁰³ is fluorine or a substituent represented by Formula A-1,
R²⁰⁴ and R²⁰⁵ are each independently selected from the group consisting of hydrogen; deuterium; halogen; a C₆-C₆₀ aryl group; a fluorenyl group; a C₂-C₆₀ heterocyclic group including at least one hetero atom of O, N, S, Si or P; a fused ring group of a C₃-C₆₀ aliphatic ring and an C₆-C₆₀ aromatic ring; a C₁-C₆₀ alkyl group; a C₂-C₂₀ alkenyl group; a C₂-C₂₀ alkynyl group; a C₁-C₃₀ alkoxyl group; and a C₆-C₃₀ aryloxy group; or R²⁰⁴ and R²⁰⁵ can be bonded to each other to form a ring,
n201 is an integer of 0 to 3, and a201, a202, a203 and a204 are each independently an integer of 1 to 10,
x is an integer of 1 to 50,
y+z is 2x+1 or 2x, wherein z is an integer greater than or equal to 1,
wherein the aryl group, heteroaryl group, arylene group, heterocyclic group, fluorenyl group, fluorenylene group, fused ring group, alkyl group, alkenyl group, alkynyl group, alkoxyl group, aryloxy group, alkylene group, alkenylene group, alkynylene group, alkoxylene group and aryloxylene group may be substituted with one or more substituents selected from the group consisting of deuterium; halogen; silane group: siloxane group; boron group; germanium group; cyano group; nitro group; C₁-C₂₀ alkylthio group; C₁-C₂₀ alkoxyl group; C₆-C₂₀ aryloxy group; C₁-C₂₀ alkyl group; C₂-C₂₀ alkenyl group; C₂-C₂₀ alkynyl group; C₆-C₂₀ aryl group; C₆-C₂₀ aryl group substituted with deuterium; C₆-C₂₀ aryl group substituted with halogen; a fluorenyl group; C₂-C₂₀ heterocyclic group; C₃-C₂₀ cycloalkyl group; C₇-C₂₀ arylalkyl group; and C₈-C₂₀ arylalkenyl group; additionally, the hydrogens of these substituents may be further substituted with one or more deuteriums, also the substituents may be bonded to each other to form a saturated or unsaturated ring, wherein the term ‘ring’ means a C₃-C₆₀ aliphatic ring or a C₆-C₆₀ aromatic ring or a C₂-C₆₀ heterocyclic group or a fused ring formed by the combination thereof.

6. The organic electronic element according to claim 1, wherein the organic electronic element comprises an anode; and an organic material layer formed between the anode and the metal electrode and the metal patterning layer.

7. The organic electronic element according to claim 6, further comprising a light efficiency enhancing layer formed on at least one surface of the anode and the metal electrode, the surface being opposite to the organic material layer.

8. The organic electronic element according to claim 6, wherein the organic material layer comprises 2 or more stacks comprising a hole transport layer, an emitting layer and an electron transport layer sequentially formed on the anode.

9. The organic electronic element according to claim 8, wherein the organic material layer further comprise a charge generation layer formed between the 2 or more stacks.

10. An electronic device comprising a display device comprising the organic electronic element of claim 1; and a control unit for driving the display device.

11. The electronic device according to claim 10, wherein the organic light-emitting display device comprises at least one of an OLED, an organic solar cell, an organic photoconductor, an organic transistor, a monochrome or white lighting element, and a display element.
